(19) United States
(12) Patent Application Publication
(10) Pub. No.: US 2026/0018377 A1
(43) Pub. Date: Jan. 15, 2026

(54) OPTIMIZATION AND ALIGNMENT OF SHAPED CHARGED PARTICLE BEAMS

(71) Applicant: FEI Company, Hillsboro, OR (US)

(72) Inventor: Garrett Budnik, Portland, OR (US)

(21) Appl. No.: 18/767,121

(22) Filed: Jul. 9, 2024

(51) Int. Cl. H01J 37/30; H01J 37/21; H01J 37/28; H01J 37/304

(52) U.S. Cl. CPC H01J 37/3007; H01J 37/21; H01J 37/28; H01J 37/304; H01J 2237/31749

(57) ABSTRACT

A focused ion beam system includes an ion source, an aperture plate having a reference aperture and a shaped aperture, a stigmator, an objective lens, and a controller. The controller directs the ion source to emit ions to form an ion beam; determines, while the ion beam passes through the reference aperture to form a reference beam, a reference stigmator voltage to minimize a dimension of the reference beam; and determines, while the ion beam passes through the shaped aperture to form a shaped working beam and while operating the stigmator using the reference stigmator voltage, a focus value of the objective lens to optimize a size of the shaped working beam. A shape of the shaped working beam is different from a shape of the reference beam and has a first dimension corresponding to the dimension of the reference beam and a second dimension larger than the first dimension.

### BACKGROUND INFORMATION

In charged particle beam systems, such as electron microscopes and focused ion beam (FIB) systems, a source generates charged particles (e.g., electrons or ions), which are focused by an optical column into a charged particle beam. The optical column directs the beam onto the surface of a sample to be processed, such as by imaging, milling, or fabrication of microstructures on the sample. The optical column may also deflect the beam to move the beam around on a surface of the sample.

Typically, a beam controller directs the beam to specified coordinates or along a specified path using a beam controller coordinate system in response to a stored program, pattern generator, or operator instructions to perform a specific process. Ideally, the beam converges in the plane of the sample. However, if the system is not calibrated, the beam may converge before or after the sample plane, causing the beam to be unfocused. Also, the beam may exhibit stigmatic effects. Moreover, there may be rotational misalignment between the axis of the specimen and the scan axis of the beam, or there may exist a non-orthogonal relationship between the beam axes. Further, the scan gain may be different in each of the orthogonal scan directions so that the image appears “stretched” in one direction. Therefore, the scanned beam system should be calibrated to eliminate or at least minimize these errors. To overcome these problems, an electron microscope or an FIB system typically provides control elements to achieve calibration. For example, an electrostatic lens system may be used converge an ion beam at the correct focal point and a stigmator may be used to adjust for astigmatism.

In some applications, an FIB system is used to process a sample to produce a lamella, which is a thin, vertical slice of the sample that can be imaged by a transmission electron microscope (“TEM”). An ion beam mills the lamella out of the sample by removing sample material to leave an exposed cross-sectional surface of the sample (the lamella) to be imaged by a TEM. Aa cross-sectional surface that is as flat and vertical as possible is obtained by a clean, fine cut by the ion beam. Therefore, transmission electron microscopy requires accurate beam positioning for the extraction of a lamella.

For precision processing in which a beam is used to mill material from a sample, the milling rate is roughly proportional to the beam current (quantity of charged particles per unit of time). For example, beams having a high beam current are preferred for quick removal of material. However, beams having a high beam current are less precise and typically result in a damaged or undesirable sample. Therefore, beams having a low beam current have been used for more precision processing applications. A beam having a low beam current can typically be focused to a smaller size than a beam having a high beam current. For example, a small beam with a low beam current is more precise and results in less unwanted damage to the sample. However, use of a beam with a low beam current reduces the rate of material removal and therefore results in a longer processing time.

It is increasingly more desirable to decrease processing time while maintaining precision. Non-round or “shaped” beams have been developed in order to increase milling speed. Shaped beams can be generated having a sharp edge for cutting away material and, at the same time, having their beam spot shapes of a size with enough beam current for quickly removing material. In some FIB systems, the shaped beam is shaped by an aperture plate positioned within the optical column. The aperture plate has one or more selectable beam-defining apertures through which charged particles pass to form a shaped beam. When a selected aperture is properly aligned with the optical axis of the FIB system, the aperture plate blocks off-axis charged particles while the charged particles that form the beam pass through the selected aperture.

The aperture plate may have several apertures of various sizes and shapes, and the apertures can be switched depending on the application by moving the aperture plate so that a different aperture is positioned in the path of the beam. For example, a beam having a desired geometrically-shaped spot is formed by a shaped aperture typically disposed between one or more lenses in an optical column. To achieve proper calibration and alignment of the shaped beam, the optical column may be a two-lens focusing column in which a first lens forms an image of the shaped beam at or near the plane of a second lens and the second lens forms an image of the shaped beam on the target plane. The lenses and other “optical” elements (e.g., a stigmator) in the beam column may use electrostatic or magnetic fields to align the beam along the optical axis and focus the beam on the target plane.

It is important for the beam to be accurately focused and compensated for aberrations. Typically, a beam is focused and aligned using known values for the optical elements, such as the lenses and stigmator, from a table of values that have been input and stored in a program or through operator instructions based on a desired beam current. However, it is difficult to predict the optimal focus and stigmator settings for shaped beams. In particular, autofocus and stigmation routines applied to elliptical beams (or other shaped beams) will typically seek out the roundest beam. However, the roundest-shaped elliptical beam is sub-optimal for milling with high throughput.

What is needed is a method and system for optimizing a shaped beam having a sharp edge to achieve clean and fine milling operations while having a high current for rapid processing.

### SUMMARY

The following description presents a simplified summary of one or more aspects of the methods and systems described herein to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects of the methods and systems described herein in a simplified form as a prelude to the more detailed description that is presented below.

In some illustrative examples, a focused ion beam system includes: an ion source; an aperture plate including a reference beam-defining aperture and a shaped beam-defining aperture; a stigmator; an objective lens for focusing the ion beam on a target plane; and a controller configured to: direct the ion source to emit ions to form an ion beam; determine, while the ion beam passes through the reference beam-defining aperture to form a reference beam, a reference stigmator voltage for operating the stigmator to minimize a dimension of the reference beam; and determine, after determining the reference stigmator voltage and while the ion beam passes through the shaped beam-defining aperture to form a shaped working beam and while operating the stigmator using the reference stigmator voltage, a focus value of the objective lens to optimize a size of the shaped working beam; wherein a shape of the shaped working beam is different from a shape of the reference beam and has a first dimension corresponding to the dimension of the reference beam and a second dimension larger than the first dimension.

In some illustrative examples, a non-transitory computer-readable medium stores instructions that, when executed, direct at least one processor of a computing device for a focused ion beam system to: direct an ion source to emit ions to form an ion beam extending through an optical column including a stigmator and an objective lens for focusing the ion beam on a target plane; determine, while the ion beam passes through a reference beam-defining aperture to form a reference beam, a reference stigmator voltage for operating the stigmator to minimize a dimension of the reference beam; and determine, after determining the reference stigmator voltage and while the ion beam passes through a shaped beam-defining aperture to form a shaped working beam and while operating the stigmator using the reference stigmator voltage, a focus value of the objective lens to optimize a size of the shaped working beam; wherein a shape of the shaped working beam is different from a shape of the reference beam and has a first dimension corresponding to the dimension of the reference beam and a second dimension larger than the first dimension.

In some illustrative examples, a system includes: one or more processors; and memory storing executable instructions that, when executed by the one or more processors, cause a computing device to: direct an ion source to emit ions to form an ion beam extending through an optical column including a stigmator and an objective lens for focusing the ion beam on a target plane; determine, while the ion beam passes through a reference beam-defining aperture to form a reference beam, a reference stigmator voltage for operating the stigmator to minimize a dimension of the reference beam; and determine, after determining the reference stigmator voltage and while the ion beam passes through a shaped beam-defining aperture to form a shaped working beam and while operating the stigmator using the reference stigmator voltage, a focus value of the objective lens to optimize a size of the shaped working beam; wherein a shape of the shaped working beam is different from a shape of the reference beam and has a first dimension corresponding to the dimension of the reference beam and a second dimension larger than the first dimension.

In some illustrative examples, a method of optimizing a shaped working beam includes: emitting ions from an ion source to form an ion beam extending through an optical column including a stigmator and an objective lens for focusing the ion beam on a target plane; directing the ion beam through a reference beam-defining aperture to form a reference beam; determining a reference stigmator voltage for operating the stigmator to minimize a dimension of the reference beam; directing, after the determining the reference stigmator voltage, the ion beam through a shaped beam-defining aperture to form the shaped working beam, wherein a shape of the shaped working beam is different from a shape of the reference beam and has a first dimension corresponding to the dimension of the reference beam and a second dimension larger than the first dimension; and determining, while operating the stigmator using the reference stigmator voltage, a focus value of the objective lens to optimize a size of the shaped working beam.

### BRIEF DESCRIPTION OF THE DRAWINGS

The accompanying drawings illustrate various embodiments and are a part of the specification. The illustrated embodiments are merely examples and do not limit the scope of the disclosure. Throughout the drawings, identical or similar reference numbers designate identical or similar elements.

FIG. 1 shows a functional diagram of an illustrative FIB system.

FIG. 2A shows an illustrative spot-burn profile of a round beam formed by a round aperture.

FIG. 2B shows an illustrative spot-burn profile of an elliptical beam formed by an elliptical aperture.

FIG. 3 shows a functional diagram of an illustrative alignment control system.

FIG. 4 shows a chart that illustrates various different combinations of a stigmator voltage correction and a focus value for a simulated elliptical ion beam.

FIG. 5 shows an illustrative method of optimizing a shaped working beam.

FIG. 6 shows a chart that graphically represents a set of reference stigmator data for a round reference beam.

FIG. 7A shows an illustrative example of a spot-burn profile generated by an elliptical beam defined by an elliptical aperture that is misaligned in a first direction (e.g., the X direction or a direction along the minor axis of the elliptical aperture).

FIG. 7B shows another illustrative example of a spot-burn profile generated by an elliptical beam.

FIG. 8 shows the variation of the X-midpoint shape parameter for a set of simulated spot-burn profiles for a 30 kV 3 nA elliptical beam having a 3:1 aspect ratio and a −50 μm defocus, each spot-burn profile having a different aperture displacement value relative to zero (indicated in the inset boxes) along the X axis.

FIG. 9 shows the variation of the angle shape parameter for the set of simulated spot-burn profiles of FIG. 8.

FIG. 10 shows an illustrative example of a spot-burn profile generated by an elliptical beam defined by an elliptical aperture that is misaligned in a second direction (e.g., the Y direction, or the direction along a major axis of the aperture).

FIG. 11 shows the variation of the Y-midpoint shape parameter for a set of simulated spot-burn profiles for a 30 kV 3 nA elliptical beam having a 3:1 aspect ratio and a −50 μm defocus, each spot-burn profile having a different aperture displacement value relative to zero (indicated in the inset boxes) along the Y axis.

FIG. 12 shows an illustrative method of aligning a shaped aperture with an ion source using a shape parameter of a spot-burn profile.

FIG. 13 shows a chart that includes a set of curves that plot the measured X-midpoint shape parameter as a function of aperture offset, where each curve represents data acquired with a unique defocus value.

FIG. 14 shows a chart that includes a set of curves that plot the measured angle shape parameter as a function of aperture offset, where each curve represents data acquired with one of the unique defocus values of FIG. 13.

FIG. 15 shows a chart that includes a set of curves that plot the measured Y-midpoint shape parameter as a function of aperture offset, where each curve represents data acquired with one of the unique defocus values of FIG. 13.

FIG. 16 shows an illustrative sensitivity plot that includes a set of curves that plot normalized sensitivity as a function of defocus value (μm) for each shape parameter alignment method.

FIG. 17 shows two different sensitivity plots each representative of different beam conditions.

FIG. 18 shows an illustrative method of aligning a shaped aperture with an ion source based on conditions of the ion beam.

FIG. 19 shows an illustrative method of aligning a shaped aperture and optimizing the shaped beam.

FIG. 20 shows an illustrative computing device that may be specifically configured to perform one or more of the processes described herein.

### DETAILED DESCRIPTION

Systems and methods for optimization of a shaped charged particle beam are described herein. For example, ions emitted from an ion source form an ion beam extending along an optical axis through an optical column. The optical column includes an objective lens for focusing the ion beam on a target plane and a stigmator for correcting astigmatism in images of a spot produced by the ion beam. While the ion beam is directed through a reference beam-defining aperture to form a reference beam, a reference stigmator voltage is determined for the stigmator. The reference stigmator voltage is selected to minimize a dimension (e.g., a diameter) of the reference beam. After the reference stigmator voltage is determined, the ion beam is directed through a shaped (e.g., elliptical) beam-defining aperture to form a shaped working beam. While the reference stigmator voltage is applied to the stigmator, a focus value of the objective lens is determined by optimizing a size of the shaped working beam.

Optimization of the stigmator voltage and the focus value for a shaped working beam is based on the principle that there is only one unique combination of stigmator voltage and focus value that optimizes a size of the shaped working beam in two dimensions (e.g., an X direction and a Y direction). The methods described herein provide a unique and efficient path to identify this unique combination of stigmator voltage and focus value, which currently available methods cannot do.

Systems and methods for alignment of a shaped charged particle beam are also described herein. A method of aperture alignment that aligns elliptical apertures to the column optical axis by centering overlapping profiles of high angle and low angle ray spot profiles. For example, an ion beam is directed through a shaped (e.g., elliptical) beam-defining aperture to form a shaped ion beam. The shaped ion beam burns a spot in a sample, and an image of the spot is acquired. A shape parameter of a spot-burn profile of the imaged spot is measured. The shape parameter is a measurable parameter that describes a characteristic or shape of the spot-burn profile. Illustrative shape parameters, and methods of selecting an appropriate shape parameter, are described in more detail below. A position of the shaped beam-defining aperture is adjusted until the measured shape parameter satisfies a threshold condition. For elliptical ion beams, a spot-burn profile of the imaged spot includes a high-angle ray spot-burn profile and a low-angle ray spot-burn profile. Alignment of an elliptical beam-defining aperture is performed by using the shape parameter to center overlapping profiles of the high-angle ray spot-burn profile and the low-angle ray spot-burn profile.

The alignment methods described herein for shaped beams do not suffer from the problems inherent with aligning shaped beams using conventional methods for round beams. Thus, the alignment methods described herein are more accurate than conventional alignment methods and enable the use of elliptical beams that could not otherwise be used due to poor alignment and, hence, poor beam quality.

Various examples will now be described in more detail with reference to the figures. The systems and methods described herein may provide one or more of the benefits mentioned above and/or various additional and/or alternative benefits that will be made apparent herein.

Illustrative systems and methods for alignment and optimization of a shaped charged particle beam may be performed by or in conjunction with a charged particle beam system. Charged particle beam systems include focused ion beam (FIB) systems and electron beam systems. The examples that follow will be described with reference to FIB systems. However, the systems and methods described herein with reference to FIB systems apply equally to any other type of charged particle beam systems, such as electron beam systems, as long as suitable optical components for such other systems are used. Accordingly, any and all uses of the term “ion beam” and “focused ion beam system” may be substituted by the terms “electron beam” and “electron beam system,” respectively, without departing from the scope of the disclosure herein. While an example of suitable hardware is provided below, the concepts described herein are not limited to being implemented in any particular type of hardware.

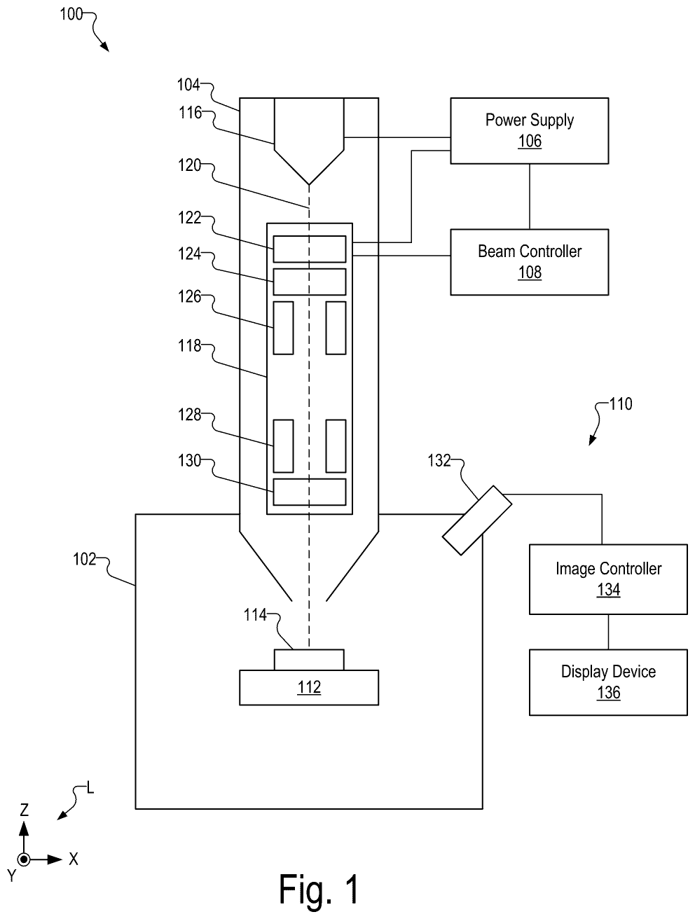

FIG. 1 shows a functional diagram of an illustrative FIB system 100. FIB system 100 includes a sample chamber 102, an evacuated chamber 104 in optical connection with sample chamber 102, a high voltage power supply 106, a beam controller 108, and an imaging system 110. A legend L is arbitrarily oriented so that the Z axis extends along an optical axis of FIB system 100, the X axis lies in the plane of the page, and the Y axis is orthogonal to the Z and X axes.

Sample chamber 102 includes a sample stage 112 on which a sample 114 is supported for processing. Sample stage 112 may be fixed or may be a movable stage (e.g., movable along one, two, or three axes). Sample 114 can be any material that may be processed (e.g., imaged or worked upon to achieve a desired result). For example, sample 114 may be a semiconductor device, a photo-lithographic mask, a magnetic storage head, and the like.

Evacuated chamber 104 includes an ion source 116 for generating ions and an optical column 118. Ion source 116 is implemented by any suitable ion source, such as a liquid metal ion source (LMIS) that provides gallium ions (or other metal ions), a multicusp ion source, or another plasma ion source. Ions from ion source 116 are extracted and formed into an ion beam 120 by extractor optics (not shown).

Optical column 118 includes various “optical” components that define and focus ion beam 120 on a target surface (focal plane) of sample 114. As used herein, the term “optical” and its related variations is not limited to light but is extended by analogy to include reference to charged particles. The various optical components included in FIB system 100 use electrostatic or magnetic fields to control or manipulate ion beam 120. Optical column 118 includes a first lens 122 (e.g., a condensing lens), an aperture plate 124, a quadrupole 126, a stigmator 128, and a second lens 130 (e.g., an objective lens). Optical column 118 may include additional or alternative components not shown in FIG. 1, such as a blanker and a Faraday cup.

First lens 122 aligns ion beam 120 to an optical axis of optical column 118 and focuses ion beam 120 on a plane of second lens 130. In some examples, the optical axis of optical column 118 passes through a center of second lens 130.

Aperture plate 124 is a plate made of metal or other material (e.g., glass, ceramic, polymer, composite, etc.) and has one or more reference beam-defining apertures and one or more shaped beam-defining apertures. A reference aperture, when aligned with ion beam 120, defines a reference beam. A shaped aperture, when aligned with ion beam 120, defines a shaped beam. Reference beams and shaped beams have different shapes and will be described below in more detail.

Aperture plate 124 may be selectively positioned to align a reference aperture or a shaped aperture with ion beam 120. Aperture plate 124 blocks off-axis ions while the ions that form ion beam 120 pass through the selected aperture. Aperture plate 124 may be manipulated (e.g., repositioned) in at least one or two directions (e.g., the X-direction and/or Y-direction) by a one- or two-axis aperture plate stage (not shown) connected to aperture plate 124 to select and align a desired aperture with ion beam 120. The aperture plate stage may be adjusted manually or driven automatically by a step-motor (which may be controlled by beam controller 108). Thus, aperture plate 124 can be moved so that an aperture of a desired size and/or shape is aligned with (e.g., positioned in the path of) ion beam 120.

Quadrupole 126 directs ion beam 120 to second lens 130. Second lens 130 may be implemented, for example, by an objective lens and focuses ion beam 120 onto a target plane (e.g., a surface of sample 114 for processing of sample 114). A focus value of second lens 130 (also referred to herein as a defocus value) may be adjusted to adjust the focal point of ion beam 120. The focus value refers to the voltage applied to second lens 130 and/or a defocus distance from the Gaussian image plane (e.g., measured in microns (μm)).

Stigmator 128 corrects or reduces astigmatism in ion beam 120 by imposing a weak electric field (or magnetic field) on ion beam 120. In some examples, stigmator 128 is implemented by a multi-pole device (e.g., a quadrupole, a hexapole, an octupole, etc.).

Beam deflectors (not shown) in optical column 118 scan ion beam 120 along the X axis and/or Y axis. Thus, ion beam 120 can be scanned to process sample 114, such as by milling, chemically enhanced etching, material deposition, and/or imaging. In some examples, stigmator 128 and the beam deflectors are implemented by the same device (e.g., an octupole that performs the functions of both a stigmator and a deflector).

High voltage power supply 106 is electrically connected to, and provides an appropriate voltage to, ion source 116 and various optical elements in optical column 118, such as to first lens 122, quadrupole 126, stigmator 128, and/or second lens 130.

Beam controller 108 is communicatively coupled with, and configured to control operations of, various components of FIB system 100. For example, beam controller 108 may control optical components of optical column 118 to manipulate ion beam 120, such as to focus, defocus, rotate, deform, reposition, and/or scan ion beam 120. In some examples, a user can provide input via a user interface device (not shown) communicatively coupled with beam controller 108 to scan ion beam 120 in a desired manner. Alternatively, beam controller 108 may access instructions (stored locally or remotely) to cause beam controller 108 to control FIB system 100 to scan ion beam 120 in a predefined path. Beam controller 108 may include any suitable hardware (e.g., a processor, circuitry, etc.) and/or software configured to control operations of and/or interface with the various components of FIB system 100.

Imaging system 110 includes a secondary emission detector 132, an image controller 134, and a display device 136. Secondary emission detector 132 is positioned at sample chamber 102 to detect secondary emission from sample 114. Secondary emission detector 132 may be implemented by any suitable detector, such as an electron multiplier. Image controller 134 is communicatively coupled to secondary emission detector 132 and is configured to control operation of secondary emission detector 132 and to receive and process signals generated by secondary emission detector 132 to generate image data representative of sample 114. Display device 136 is any suitable display device (e.g., a monitor, a touchscreen device, a mobile device, etc.) communicatively coupled to image controller 134 and is configured to display images based on the image data generated by image controller 134. Thus, a user may view images of sample 114 while sample 114 is processed by ion beam 120.

The identified components of FIB system 100 are not required in all applications, and FIB system 100 may include additional or alternative components not shown in FIG. 1 as may suit a particular implementation, such as a suppressor, an ion pump, a pumping system, a vacuum control system, and/or a gas delivery system. While optical column 118 uses a two-lens ion focusing structure for generating and focusing ion beam 120, optical column 118 may include any other suitable number of lenses. In some systems, one or more optical components (e.g., deflection plates, stigmator 128, and/or other optical components) are placed outside of optical column 118 after second lens 130. Moreover, the depicted sizes and relative positions of components are not necessarily to scale or consistent with all configurations. While FIG. 1 shows that FIB system 100 is arranged in a projection approach, the components of FIB system 100 may alternatively be arranged in an angular aperture approach.

In some examples, FIB system 100 is part of a dual beam scanning electron microscope (SEM)-FIB system. A dual beam SEM-FIB system may include a vertically mounted SEM column (not shown) and an FIB column (e.g., evacuated chamber 104) mounted at an angle (e.g., an angle of approximately 52 degrees) from the vertical.

In some applications, FIB system 100 is used to process sample 114 for imaging by a TEM. In these applications, ion beam 120 mills a “lamella”—a thin, vertical slice—out of the surface of sample 114 by removing material to leave an exposed cross-sectional surface to be imaged by a TEM. A cross-sectional surface that is as flat and vertical as possible is obtained by a clean, fine cut by ion beam 120.

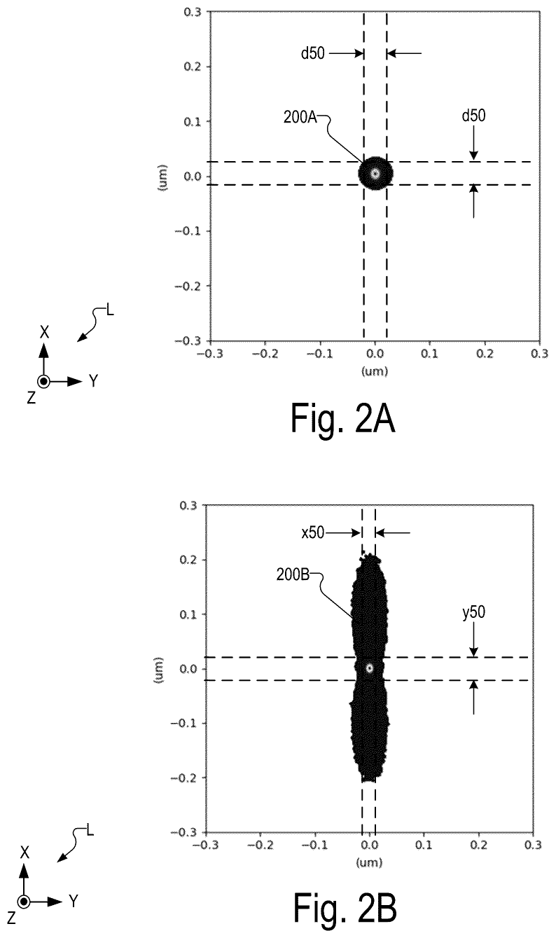

In lamella milling, a working beam having a beam current between about 40-90 picoamps (pA) provides a sharp edge that makes a clean cut and prevents damage to the lamella. Beams having current within this range are typically round. FIG. 2A shows an illustrative spot-burn profile 200A of a round beam formed by a round aperture. Spot-burn profile 200A is obtained by burning a spot in a sample using a round ion beam and capturing an image of the spot (e.g., by imaging system 110). A portion of the round beam that contains 50% of the current has a dimension (e.g., diameter) referred to as d50, which is indicated by dashed lines.

However, a higher beam current than what is conventionally used with round beams (e.g., greater than about 90 pA) is desired to decrease processing time. Higher beam current can be achieved using a shaped (non-round) beam, such as an elliptical beam. The minor axis of an elliptical beam may be the same as a round beam but the major axis is longer than the diameter of the round beam (in some examples, up to twice or three times longer). As a result, elliptical beams have more current in the cutting edge, thus allowing the elliptical beams to remove more material and thereby increase throughput of lamellae processing.

FIG. 2B shows an illustrative spot-burn profile 200B of an elliptical beam formed by an elliptical aperture. Spot-burn profile 200B is obtained by burning a spot in a sample using an elliptical ion beam and capturing an image of the spot (e.g., by imaging system 110). As shown by spot-burn profile 200B, a portion of the elliptical beam that contains 50% of the current along a first direction (e.g., along the X axis or the minor axis of the elliptical beam) has a first dimension referred to as x50 (indicated by dashed lines). A portion of the elliptical beam that contains 50% of the current along a second direction (e.g., along the Y axis or the major axis of the elliptical beam) has a second dimension referred to as y50 (indicated by dashed lines).

While shaped ion beams, such as elliptical beams, have higher current than round beams, shaped apertures are notoriously difficult to align to the ion source. Existing methods used to align round apertures are not accurate or reliable when used to align shaped apertures. Round apertures are traditionally aligned with the ion source by sweeping the voltage applied to the objective lens between upper and lower values to focus/defocus the beam spot. When the round aperture is not aligned, the sweep causes an image of a spot produced by the ion beam (e.g., an image captured and displayed by imaging system 110) to shift along an axis (e.g., the X-axis) and go in and out of focus. The round aperture is aligned to the optical axis by observing and/or measuring the image shift and adjusting the position of the round aperture (e.g., by adjusting a position of aperture plate 124 or by adjusting quadrupole deflectors) until the position of the imaged spot no longer shifts during the sweep.

On the other hand, an elliptical beam envelope near the focal plane is very complex and results in issues that disrupt alignment using round beam alignment techniques. For example, the voltage sweep results in two imaged spots (a double image), and each imaged spot shifts in a different direction during the sweep. As a result, it is difficult to correlate the spot shift with the elliptical aperture alignment. That is, it is difficult to know which direction to adjust the position of the elliptical aperture. Additionally, the unfocused elliptical beam causes sample damage due to non-uniform split beams.

A spot produced by an elliptical beam has very few features to analyze for aperture alignment and focus adjustment. The evolution of the spot with defocus of the elliptical beam (especially with misaligned elliptical apertures) is complicated, and the amount that the spot profile changes per aperture offset is different for different beam shapes and sizes.

Optimization of a stigmator voltage to correct astigmatism caused by a shaped beam and optimization of a focus value for the shaped beam are also difficult, and current techniques cannot find an optimal combination of stigmator voltage and focus value. Images from elliptical shaped beams inherently have astigmatism and thus are blurry and fuzzy, and the response of the image with change in focus and stigmator correction is unnatural compared to round beam behavior. When optimizing a round beam, a user or a computer will adjust the focus and the stigmator to achieve the sharpest, most symmetrical beam. This condition is described as equal parts x50 and y50. When the round beam is modified with the stigmators, the beam can squish in the X direction or Y direction slightly, but it is clear that the response becomes asymmetrical (e.g., y50>x50 or vice versa) in these conditions. This is intuitive for a user to see and correct.

With conventional methods of setting stigmator voltages and focus values for an elliptical beam, only one dimension is minimized (e.g., the minor axis dimension (x50)), but the elliptical beam is very asymmetrical (e.g., y50>>x50). Thus, a user will tend to adjust the stigmators and navigate towards the symmetric condition where x50 and y50 are about equal, but this is a much poorer beam to use. To avoid driving to the symmetric point, a prior solution was developed that determines the stigmator correction and focus value for a reference beam (e.g., a round reference beam) and uses both the stigmator correction and focus value for a corresponding elliptical beam. This solution is described in U.S. Pat. No. 9,679,742, issued Jun. 13, 2017, which is incorporated herein by reference in its entirety. This is an improvement over conventional techniques, but it still does not get the best possible condition of the elliptical beam.

The systems and methods described herein improve the optimization of shaped beams by using a reference beam (e.g., a round beam) to determine a stigmator voltage to be applied to a stigmator for a shaped (e.g., elliptical) beam, and using the shaped beam to determine an optimal focus value. Additionally, the systems and methods described herein improve alignment of shaped (e.g., elliptical) apertures as compared with conventional alignment techniques by measuring and analyzing one or more shape parameters of spot-burn profile of a spot produced by the shaped beam.

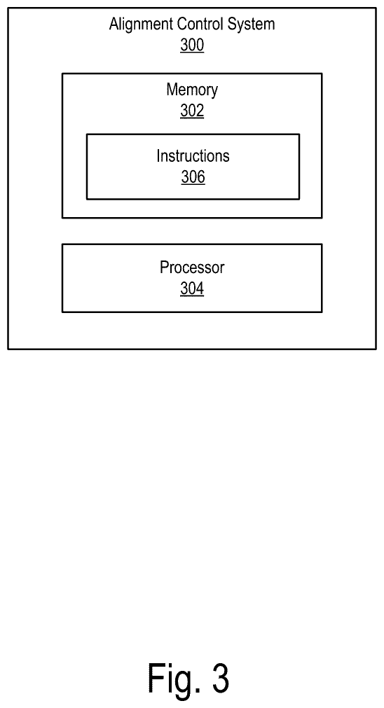

One or more operations associated with optimization and alignment of a shaped beam may be performed by an alignment control system. FIG. 3 shows an illustrative alignment control system 300 (“control system 300”). System 300 may be implemented entirely or in part by FIB system 100 (e.g., by beam controller 108 and/or image controller 134). Alternatively, control system 300 may be implemented separately from FIB system 100 (e.g., by a separate computing system communicatively coupled with FIB system 100).

Control system 300 may include, without limitation, a memory 302 and a processor 304 selectively and communicatively coupled to one another. Memory 302 and processor 304 may each include or be implemented by hardware and/or software components (e.g., processors, memories, communication interfaces, instructions stored in memory for execution by the processors, etc.). In some examples, memory and processor may be distributed between multiple devices and/or multiple locations as may serve a particular implementation.

Memory 302 may maintain (e.g., store) executable data used by processor 304 to perform any of the operations described herein. For example, memory 302 may store instructions 306 that may be executed by processor 304 to perform any of the operations described herein. Instructions 306 may be implemented by any suitable application, software, code, and/or other executable data instance. Memory 302 may also maintain any data acquired, received, generated, managed, used, and/or transmitted by processor 304.

Processor 304 may be configured to perform (e.g., execute instructions 306 stored in memory 302 to perform) various processing operations described herein. It will be recognized that the operations and examples described herein are merely illustrative of the many different types of operations that may be performed by processor 304. In the description herein, any references to operations performed by system 300 may be understood to be performed by processor 304 of system 300. Furthermore, in the description herein, any operations performed by system 300 may be understood to include system 300 directing or instructing another system, device, apparatus, or computing system to perform the operations.

Optimization of a shaped beam will now be described. As used herein, “optimize” and its variants means to seek an improved or optimum solution among a set of possible solutions, although the absolute best solution may not necessarily be obtained, such as when an optimization process is terminated prior to finding the best solution, when multiple solutions exist that satisfy predefined criteria, when a solution satisfies minimum criteria, or when a selected optimization technique is unable to converge on the best solution. Similarly, as used herein an “optimum” parameter (e.g., a “maximum” or “minimum” value of a parameter) means the solution obtained as the result of performing an optimization process, and thus may not necessarily be the absolute extreme value of the parameter (e.g., the absolute maximum or minimum), but still adjusts the parameter and results in an improvement.

In some examples, a shaped beam is optimized when both x50 and y50 dimensions are at a minimum value. In other examples, a shaped beam is optimized when both x50 and y50 dimensions are within a threshold amount of the respective minimum value, such as a threshold percentage (e.g., within 3%, 5%, 10%, etc.) or a threshold distance (e.g., 3 nm, 5 nm, 10 nm, 15 nm, etc.). The threshold percentage or threshold distance may be the same for both x50 and y50, or they may be different, and the threshold percentage or threshold distance may be different for different aspect ratios of the elliptical beam.

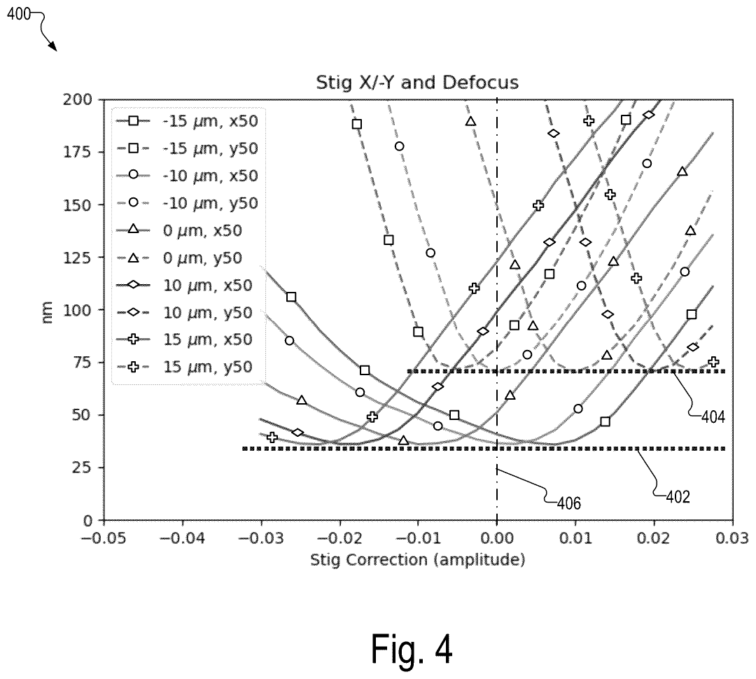

FIG. 4 shows a chart 400 that illustrates various different combinations of a stigmator voltage correction and a focus value for a simulated elliptical ion beam having a 3:1 aspect ratio (Y/X ratio) and an aligned aperture (which in this simulation is assumed to produce no astigmatism). Chart 400 includes a set of curves that plot a first dimension (x50, shown in solid line curves) and a second dimension (y50, shown in dashed line curves) as a function of an amplitude perturbation of the beam (which manifests as a stigmator voltage correction) for each of a set of defocus values (defocus values of −15 μm, −10 μm, 0 μm, 10 μm, and 15 μm). As can be seen in chart 400, for any given defocus value, either x50 or y50 can be minimized by adjusting the stigmator voltage (which adjusts the amplitude perturbation), as indicated by dashed horizontal lines 402 and 404 representing the minimum of x50 and y50, respectively. However, there is only one combination of stigmator voltage correction and defocus value that minimizes both x50 and y50, as indicated by vertical dash-dot-dash line 406. In the example of FIG. 4, the optimum combination is a stigmator voltage correction of zero (given the assumption for this simulated beam that the system is perfectly aligned and thus produces no astigmatism for the reference beam) and a defocus value of −10 μm from the Gaussian image plane.

To determine the optimum stigmator voltage and focus value for a shaped beam, the x50 and y50 dimensions could be measured as a function of stigmator voltage across a range of stigmator voltages for each of a plurality of different focus values to obtain a set of data similar to the data represented by chart 400. However, such a process would be time consuming and inefficient. The methods that will be described below provide a simple and efficient path to determine the optimum stigmator voltage and focus value to optimize a shaped working beam.

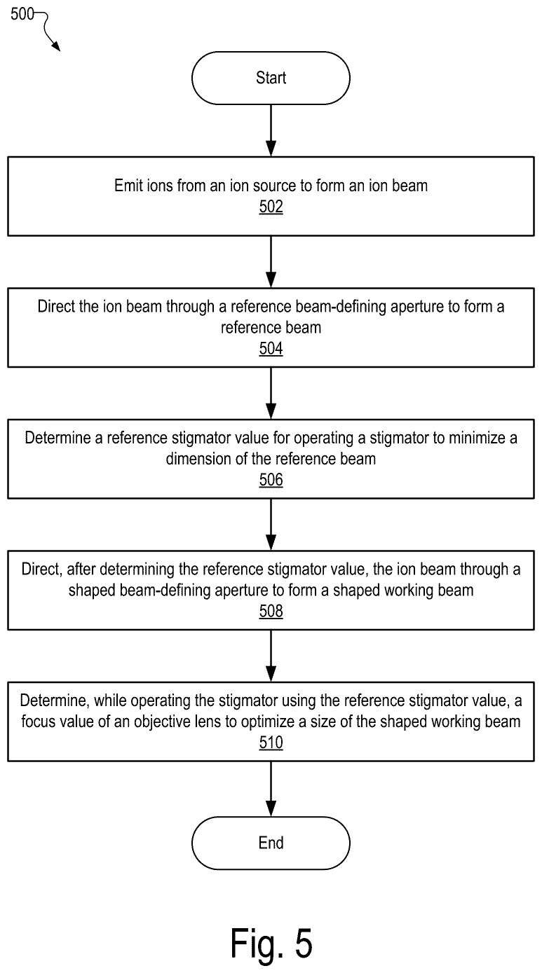

FIG. 5 shows an illustrative method 500 of optimizing a shaped working beam. While FIG. 5 shows illustrative operations according to one embodiment, other embodiments may omit, add to, reorder, and/or modify any of the operations shown in FIG. 5. Any one or more of the operations of method 500 may be performed by control system 300.

At operation 502, ions are emitted from an ion source to form an ion beam (e.g., ion beam 120) extending through an optical column (e.g., optical column 118) having optical components extending along an optical axis. The optical components include at least a stigmator (e.g., stigmator 128) for correcting astigmatism and an objective lens (e.g., second lens 130) for focusing the ion beam on a target plane (e.g., a surface of sample 114).

At operation 504, the ion beam is directed through a reference beam-defining aperture to form a reference beam having a reference beam shape. To this end, an aperture plate is moved so that the reference beam-defining aperture is in the path of the ion beam. In some examples, the reference beam aperture is round (e.g., substantially circular) and forms a round reference beam. It will be recognized that the reference beam aperture may have any other suitable shape that may be used as a reference to determine a stigmator voltage.

At operation 506, a reference stigmator voltage for operating the stigmator is determined so that a dimension of the reference beam is minimized. For example, when the reference beam is round, the stigmator voltage is adjusted to minimize d50 of the round reference beam. The stigmator voltage thus determined is applied to the stigmator and may be “locked” in place so that the stigmator voltage is not or cannot be changed while optimizing the focus value for the shaped working beam.

The reference stigmator voltage may be determined by sweeping the stigmator voltage across a range of stigmator voltages (e.g., from 10 kV to 15 kV) and, at each stigmator voltage, collecting an image of the spot and measuring, based on a spot-burn profile in the image of the spot, the dimension of the reference beam. The dimension of the reference beam may be measured in any suitable way. In some examples, the dimension of the reference beam is measured by control system 300 without user input by using image recognition and image processing techniques. In other examples, the dimension of the reference beam is measured by control system 300 based on user input. For example, a user may measure the dimension of the reference beam using virtual measurement tools provided by a graphical user interface coupled with control system 300. Based on the measurements, a set of reference stigmator data is generated that represents the dimension of the reference beam as a function of stigmator voltage. The stigmator voltage corresponding to the minimum value of the dimension of the reference beam is selected as the reference stigmator voltage. In some examples, the minimum value of the dimension of the reference beam is determined by interpolation of the reference stigmator data.

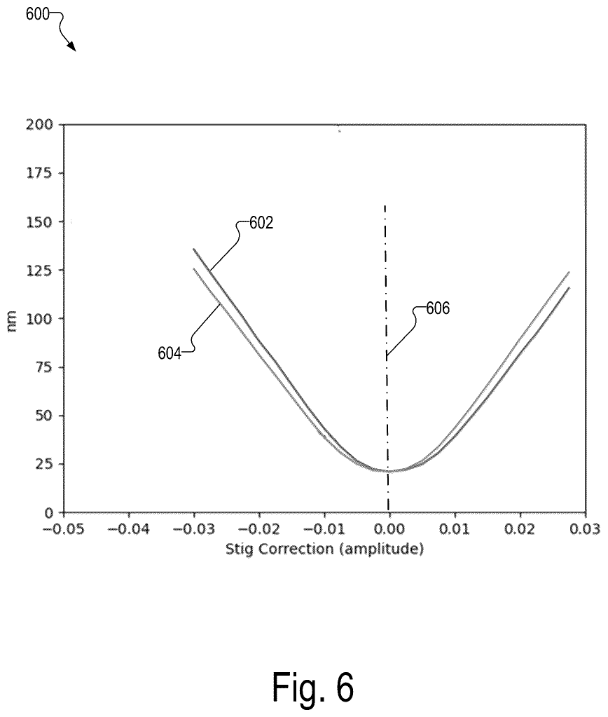

Operation 506 is illustrated in FIG. 6. FIG. 6 shows a chart 600 that graphically represents a set of reference stigmator data for a round reference beam, assuming the aperture is aligned with the optical column and thus produces no astigmatism. Chart 600 includes a curve 602 that plots a first dimension (x50) of the round reference beam as a function of stigmator voltage correction and a curve 604 that plots a second dimension (y50) of the round reference beam as a function of a stigmator voltage correction. Since the reference beam is round, the first dimension and second dimension are the same dimension (e.g., d50). The stigmator voltage correction at the minimum value of the first dimension or the second dimension is selected as the reference stigmator voltage. In the example of FIG. 6, the minimum value of the dimension of the reference beam occurs at a stigmator voltage correction of zero (given the assumption for this simulation that the system is perfectly aligned and thus produces no astigmatism for the reference beam), as indicated by dash-dot-dash line 606.

Returning to FIG. 5, at operation 508, after the reference stigmator voltage is determined, the ion beam is directed through a shaped beam-defining aperture to form a shaped working beam. For example, aperture plate 124 may be adjusted to move a desired shaped aperture into the path of ion beam 120. In some examples, the shaped aperture is elliptical and forms an elliptical working beam. The shaped working beam has a first dimension (e.g., a minor axis diameter) corresponding to the dimension (e.g., diameter) of the reference beam and a second dimension (e.g., a major axis diameter) larger than the first dimension. An aspect ratio of the second dimension to the first dimension is greater than 1.0. In some examples, the aspect ratio is 1.2:1 or greater, 1.5:1 or greater, 1.75:1 or greater, 2:1 or greater, 2.5:1 or greater, 3:1 or greater, 3.5:1 or greater, 1.7:1.5, or any other suitable aspect ratio.

By selecting the shaped aperture so that the shaped working beam has a first dimension corresponding to the dimension of the reference beam, the reference stigmator voltage determined at operation 506 will also be the optimum stigmator voltage for the shaped working beam. A shaped aperture corresponds to a reference aperture when the first dimension of the shaped aperture and the dimension of the corresponding reference aperture are substantially the same. However, the second dimension of the shaped aperture and the dimension of the corresponding reference aperture are different. For example, the diameter of the minor axis of an elliptical aperture corresponds to the diameter of a round reference aperture while the diameter of the major axis of the elliptical aperture is greater than the diameter of the round reference aperture.

The aperture plate may have any suitable number of reference apertures and shaped apertures as may suit a particular implementation. Moreover, multiple different shaped apertures, each having the same first dimension but a unique second dimension, may correspond to the same reference aperture. Moreover, any one or more shaped apertures may have a shape other than elliptical, such as square, rectangular, triangular, oval, irregular, semi-circular (e.g., D-shaped), or any other non-round shape. In some implementations of method 500, the reference aperture is round (e.g., circular) and the shaped apertures is elliptical or oval. Thus, a desired shaped aperture may be selected to produce a desired shaped working beam.

At operation 510, while operating the stigmator using the reference stigmator voltage determined at operation 506, a focus value of the objective lens (e.g., the voltage applied to the objective lens or a defocus length) is selected so that a size of the shaped working beam is optimized. For example, the size of an elliptical working beam is optimized by determining a minimum value of the first dimension (e.g., x50) or a minimum value of the second dimension (e.g., y50) of the elliptical working beam. The optimal stigmator voltage determined at operation 506 will result in a minimum or near minimum value of both the first dimension and the second dimension.

In some examples, the focus value of the objective lens is determined by minimizing the first dimension or the second dimension of the shaped working beam. The first dimension or the second dimension is minimized by sweeping the focus voltage applied to the objective lens across a range of voltages (e.g., from 10 kV to 15 kV) while operating the stigmator at the reference stigmator voltage, collecting an image of the spot at each focus voltage, and measuring, based on a spot-burn profile of the image of the spot, at least one of the first dimension or the second dimension of the shaped working beam. The first dimension and/or second dimension of the shaped working beam may be measured in any suitable way, including any way described herein. Based on the measurements, a set of focus data is generated that represents the first dimension and/or the second dimension of the shaped working beam as a function of focus value (e.g., focus voltage or defocus distance). The focus value corresponding to the minimum value of the first dimension or the second dimension of the shaped working beam is selected as the focus value to be used, in conjunction with the reference stigmator voltage determined at operation 506, for processing the sample. In some examples, the minimum value of the first dimension and/or the second dimension of the shaped working beam is determined by interpolation of the focus data.

Method 500 provides an efficient and accurate determination of the optimal combination of the stigmator voltage and the focus value for a shaped ion beam, such as an elliptical beam, which could not previously be determined using conventional techniques. Method 500 thus removes astigmatism in images produced using shaped beams, achieves an optimal focus, and produces a beam that is substantially symmetrical. Shaped ion beams that are optimized according to method 500 also have a sharp edge for clean, fine cuts while having a high current for rapid sample processing. In some examples, a shaped ion beam optimized according to method 500 has a beam current greater than 90 pA, 100 pA, 150 pA, 200 pA, 300 pA, 500 pA, 750 pA, 1 nanoamp (nA), 2 nA, or 3 nA. Method 500 can be performed relatively efficiently without consuming significant instrument resources or taking significant amounts of time for instrument setup and configuration sample. Moreover, method 500 is intuitive and natural to a user since it produces a substantially symmetrical shaped beam.

Illustrative methods for alignment of a shaped aperture to an ion source of an FIB system will now be described. A shaped aperture is aligned to an ion source based on a spot-burn profile generated by the shaped beam. Specifically, the shaped aperture is aligned by optimizing one or more shape parameters of a spot-burn profile generated by a shaped beam. A shape parameter is a parameter that describes a characteristic or shape of the spot-burn profile. In some examples, a shape parameter is a measurable parameter (e.g., distance, angle, circumference, area, radius, diameter, arclength, etc.) that quantifies a positional relationship between an overlapping low-angle ray portion of a spot-burn profile and a high-angle ray portion of the spot-burn profile. Illustrative shape parameters will be described below in more detail. The one or more shape parameters may be optimized by iteratively adjusting a position of the aperture in a first direction (e.g., the X direction) and/or in a second direction (e.g., the Y direction) until the one or more shape parameters satisfies a threshold condition. In each iteration, the shaped beam burns a spot and an image of the spot-burn is acquired (e.g., by imaging system 110) and analyzed to determine the shape parameter of the spot-burn profile.

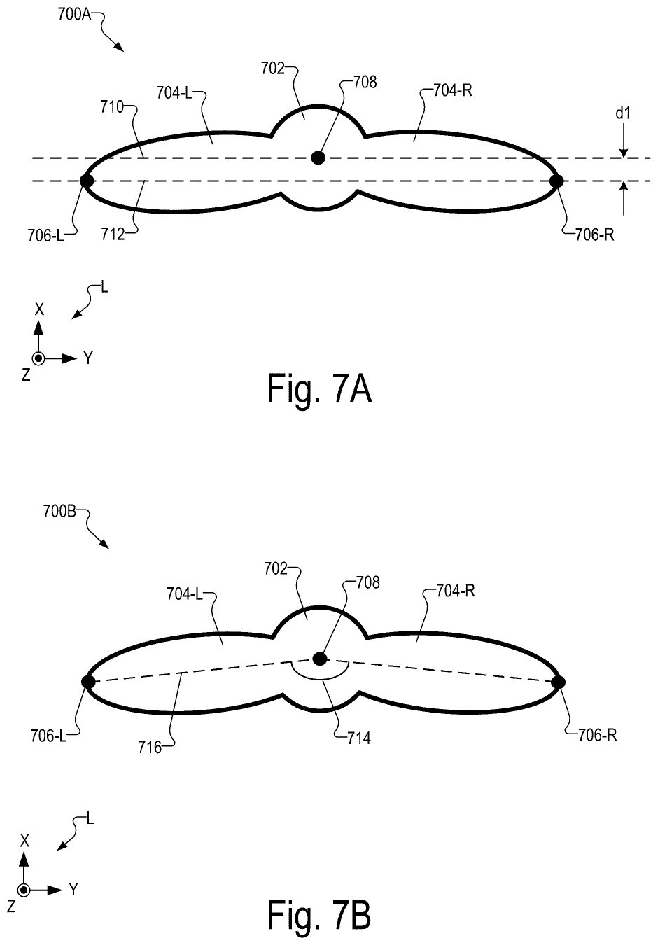

In some examples in which the aperture is adjusted along a first direction (e.g., the X direction, or the direction of the minor axis of the elliptical aperture), the shape parameter of the spot-burn profile is the distance, along the first direction, between a midpoint of a low-angle ray portion of the spot-burn profile and an axis connecting outermost apex points of a high-angle ray portion of the spot-burn profile (referred to herein as the “X-midpoint shape parameter”). FIG. 7A shows an illustrative example of a spot-burn profile 700A generated by an elliptical beam defined by an elliptical aperture that is misaligned in a first direction (e.g., the X direction or a direction along the minor axis of the elliptical aperture). Spot-burn profile 700A includes a low-angle ray portion 702 and a high-angle ray portion 704. Low-angle ray portion 702 is formed by a stream of ions having a low angle relative to the optical axis and is ideally located at the center of spot-burn profile 700A. High-angle ray portion 704 is formed by a stream of ions having a high angle relative to the optical axis and includes a left-side portion 704-L extending outward from low-angle ray portion 702 in the −Y direction and a right-side portion 704-R extending outward from low-angle ray portion 702 in the +Y direction. Left-side portion 704-L has a generally elliptical shape and an outermost apex point 706-L. Similarly, right-side portion 704-R has a generally elliptical shape and an outermost apex point 706-R. Outermost apex points 706-L and 706-R are points located at terminal ends of the major axes of left-side portion 704-L and right-side portion 704-R, respectively. In FIG. 7A, a legend L has the same orientation as in FIG. 1 so that an optical axis extends in the Z direction.

In the example of FIG. 7A, the shape parameter of spot-burn profile 700A is the distance d1 along the first direction (the X direction) between a midpoint 708 of low-angle ray portion 702 (as indicated by dashed line 710) and an axis (indicated by dashed line 712) connecting outermost apex points 706-L and 706-R. In the example of FIG. 7A, the elliptical aperture is misaligned in the X direction, and thus spot-burn profile 700A is asymmetrical across the Y axis and has a curvature such that the distance d1 is greater than zero. An ideal spot-burn profile 700A would have no curvature such that the distance d1 is zero and spot-burn profile 700A is symmetrical across the Y axis.

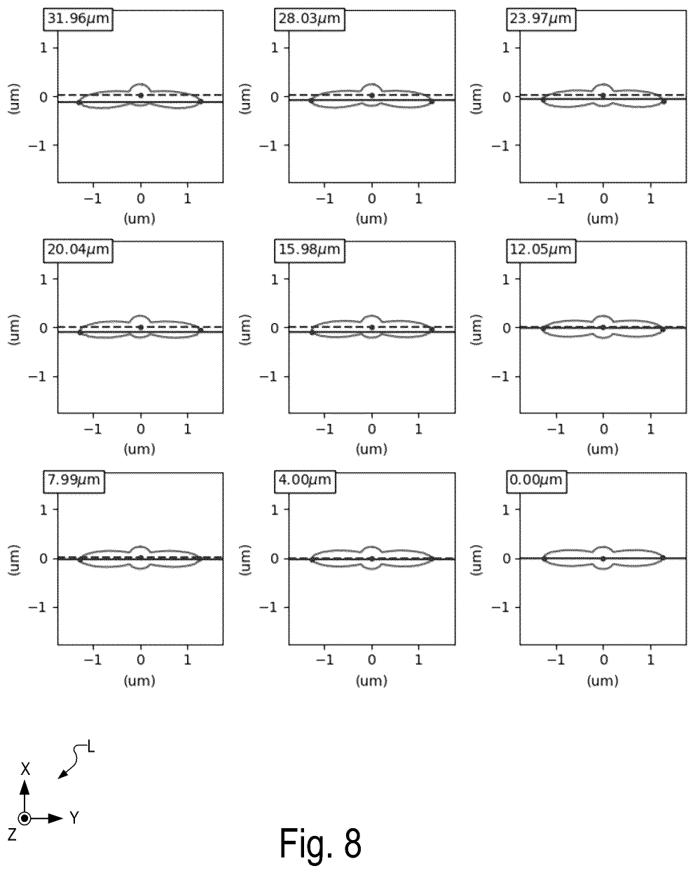

FIG. 8 shows the variation of the distance d1 for a set of simulated spot-burn profiles for a 30 kV 3 nA elliptical beam having a 3:1 aspect ratio and a −50 μm defocus, each spot-burn profile having a different aperture displacement value relative to zero (indicated in the inset boxes) along the X axis. The set of simulated spot-burn profiles is obtained by adjusting the elliptical aperture in approximately 4 μm steps in the X direction, where the ideal spot-burn profile is assigned an alignment position of 0.00 μm. As can be seen in FIG. 8, the greater the misalignment (e.g., the greater the distance in X from 0.00 μm), the greater the curvature in the spot-burn profile and, hence, the greater the distance d1. In FIG. 8, misalignments in the +X direction (e.g., greater than 0.00 μm) cause a curvature in the −X direction. Although not shown, misalignments in the −X direction would cause a curvature in the +X direction.

An ideal spot-burn profile 700A may not always be achievable (e.g., based on a step size of adjustments of the shaped aperture), so an optimized spot-burn profile approximates the ideal spot-burn profile within an acceptable tolerance. In some examples, spot-burn profile 700A is optimized when distance d1 is less than a threshold distance d1 value. The threshold distance d1 value may be set by a user, may be set based on a size and/or shape of the shaped aperture, and/or may be determined empirically. In other examples, spot-burn profile 700A is optimized when distance d1 is minimized, within an acceptable tolerance.

In other examples in which the aperture is adjusted along the first direction (e.g., the X direction, or the direction of the minor axis of the elliptical aperture), the shape parameter of the spot-burn profile is the angle formed by an axis connecting outermost apex points of a high-angle ray portion of the spot-burn profile through a midpoint of a low-angle ray portion of the spot-burn profile (referred to herein as the “angle shape parameter”). FIG. 7B shows another illustrative example of a spot-burn profile 700B generated by an elliptical beam. Spot-burn profile 700B is similar to spot-burn profile 700A. An axis 716 (indicated by the dashed line) connects outermost apex points 706-L and 706-R through midpoint 708. In the example of FIG. 7B, the shape parameter of spot-burn profile 700B is the angle 714 of axis 716, as measured from the right side of axis 716 clockwise to the left side of axis 716. However, it will be understood that the angle of axis can be measured in any other suitable way, such as the deviation from 180° (e.g., 3°, 5°, 10°, etc.). An ideal spot-burn profile 700B would have no curvature such that the angle 714 is 180°.

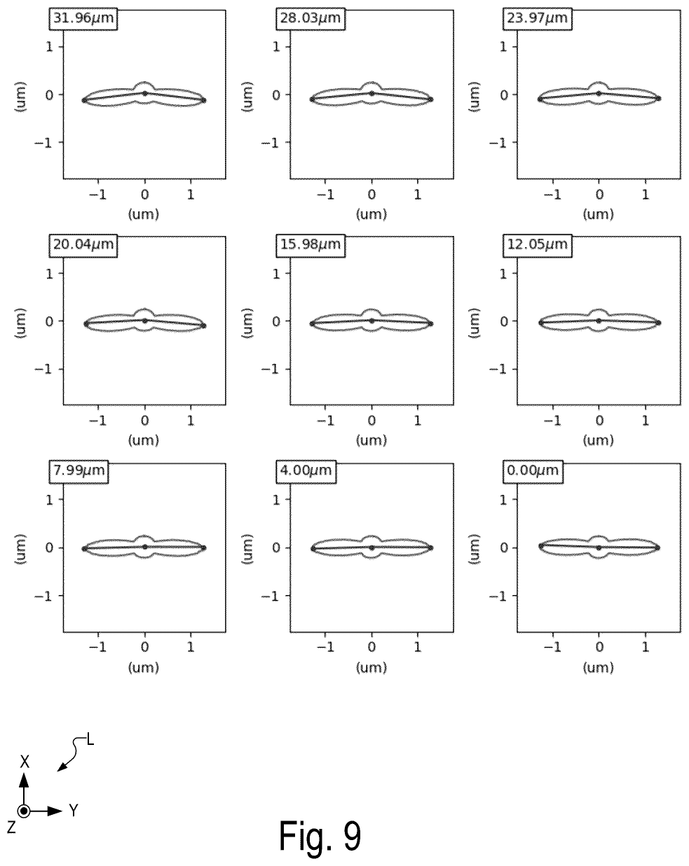

FIG. 9 shows the variation of the angle of the axis for the set of simulated spot-burn profiles of FIG. 8. As can be seen, the greater the misalignment is in the X direction (e.g., the greater the distance in X from 0.00 μm), the greater the curvature is in the spot-burn profile and, hence, the greater the angle of the axis.

An ideal spot-burn profile 700B may not always be achievable (e.g., based on a step size of adjustments of the shaped aperture), so an optimized spot-burn profile approximates the ideal spot-burn profile within an acceptable tolerance. In some examples, spot-burn profile 700B is optimized when angle 714 of the axis 716 is within a threshold range (e.g., between 170° and 190°, between 175° and 185°, between 178° and 182°, inclusive). The threshold range of the angle 714 of axis 716 may be set by a user, may be set based on a size and/or shape of the shaped aperture, and/or may be determined empirically. It will be recognized that the threshold range of angle 714 may be different depending on how angle 714 is measured. In other examples, spot-burn profile 700B is optimized when the angle 714 of the axis 716 is minimized, within an acceptable tolerance.

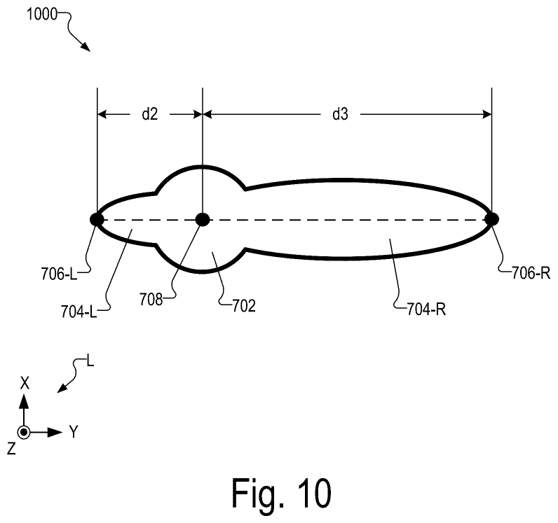

In other examples in which the aperture is adjusted along a second direction (e.g., the Y direction, or the direction of the major axis of the elliptical aperture), the shape parameter of the spot-burn profile is the distance, along the second direction, between a midpoint of a low-angle ray portion of the spot-burn profile and outermost apex points of a high-angle ray portion of the spot-burn profile (referred to herein as the “Y-midpoint shape parameter”). FIG. 10 shows an illustrative example of a spot-burn profile 1000 generated by an elliptical beam defined by an elliptical aperture that is misaligned in a second direction (e.g., the Y direction, or the direction along a major axis of the aperture). Spot-burn profile 1000 is similar to spot-burn profile 700A except that spot-burn profile 1000 is asymmetrical across the X axis because the elliptical aperture is misaligned in the second direction.

In the example of FIG. 10, the shape parameter of spot-burn profile 1000 is based on a distance d2, along the second direction (e.g., the Y direction), between midpoint 708 of low-angle ray portion 702 and outermost apex point 706-L of left-side portion 704-L and a distance d3, along the second direction, between midpoint 708 of low-angle ray portion 702 and outermost apex point 706-R of right-side portion 704-R. In the example of FIG. 10, the elliptical aperture is misaligned in the Y direction, and thus spot-burn profile 1000 is asymmetrical across the X axis such that the distance d3 is greater than the distance d2. In an ideal spot-burn profile 1000 the distance d2 and the distance d3 would be the same so that spot-burn profile 1000 is symmetrical across the X axis. In the description that follows, the Y-midpoint shape parameter is represented as the ratio d3/d2. However, the Y-midpoint shape parameter may be represented in any other suitable way, such as the difference between d3 and d2 (e.g., d3-d2), the maximum or minimum of d2 or d3.

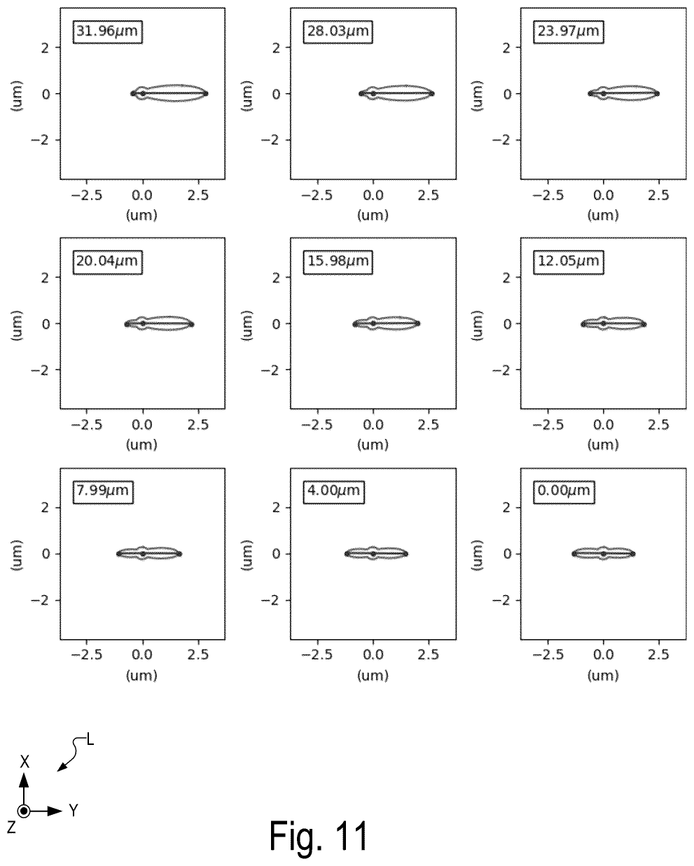

FIG. 11 shows the variation of the distance d2 and d3 for a set of simulated spot-burn profiles for a 30 kV 3 nA elliptical beam having a 3:1 aspect ratio and a −50 μm defocus, each spot-burn profile having a different aperture displacement value relative to zero (indicated in the inset boxes) along the Y axis. The set of simulated spot-burn profiles is obtained by adjusting the elliptical aperture in approximately 4 μm steps, where the ideal spot-burn profile is assigned an alignment position of 0.00 μm. As can be seen, the greater the misalignment (e.g., the greater the distance from 0.00 μm in the Y direction), the greater the offset of low-angle ray portion 702 in the spot-burn profile and, hence, the greater the ratio of the distance d3 to the distance d2 (d3/d2). In FIG. 11, misalignments in the +Y direction (e.g., greater than 0.00 μm) cause the low-angle ray portion 702 to be offset in the −Y direction. Although not shown, misalignments in the −Y direction would cause the low-angle ray portion 702 to be offset in the +Y direction.

An ideal spot-burn profile 1000 may not always be achievable (e.g., based on a step size of adjustments of the shaped aperture), so an optimized spot-burn profile 1000 approximates the ideal spot-burn profile within an acceptable tolerance. In some examples, spot-burn profile 1000 is optimized when the ratio d3/d2 (or the difference d3−d2) is within a threshold range (e.g., from 0.90 to 1.1, from 0.95 to 1.05, or from 0.975 to 1.025). The threshold range may be set by a user, may be set based on a size and/or shape of the shaped aperture, and/or may be determined empirically. In other examples, spot-burn profile 1000 is optimized when the ratio d3/d2 is minimized, within an acceptable tolerance.

In the examples described above, the shape parameter is optimized to align the shaped aperture in the first direction or in the second direction. In some examples, the aperture is aligned in both the first direction and the second direction using various different shape parameters. That is, the aperture is aligned in the first direction using the X-midpoint shape parameter or the angle shape parameter and is aligned in the second direction using the Y-midpoint shape parameter.

In the examples above, the shape parameters for an elliptical beam include an X-midpoint shape parameter, an angle shape parameter, and a Y-midpoint shape parameter. It will be understood that other shape parameters may be used, and that other shaped beams may be aligned using any other suitable shape parameters. Moreover, shape parameters may be determined based on any suitable characteristic or feature (e.g., axis, point, corner, etc.) of a spot-burn profile.

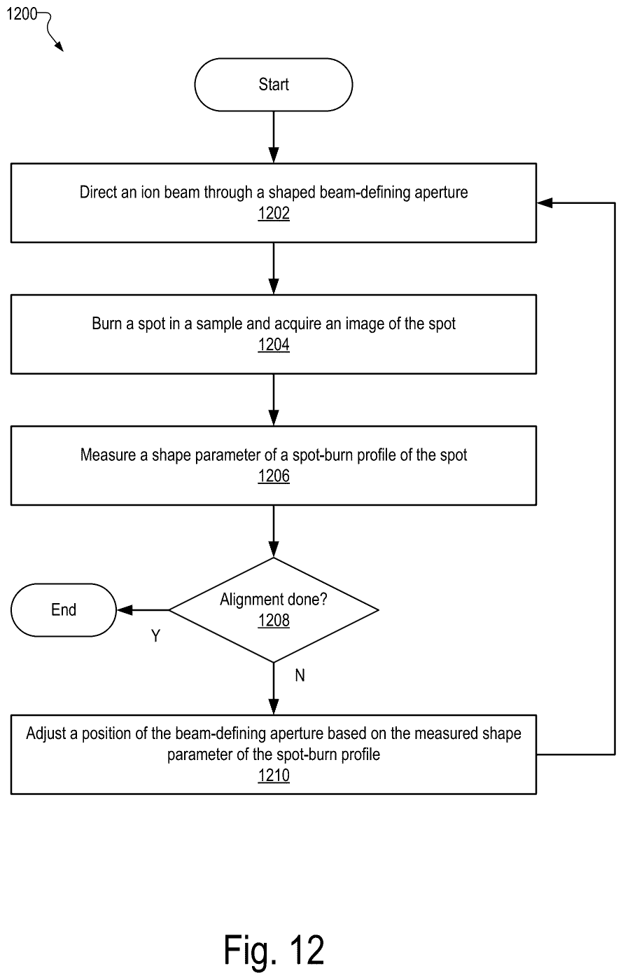

FIG. 12 shows an illustrative method 1200 of aligning a shaped aperture with an ion source using a shape parameter of a spot-burn profile. While FIG. 12 shows illustrative operations according to one embodiment, other embodiments may omit, add to, reorder, and/or modify any of the operations shown in FIG. 12. Any one or more of the operations of method 500 may be performed by control system 300.

At operation 1202, an ion beam is directed though a shaped aperture, such as an elliptical aperture, to form a shaped ion beam.

At operation 1204, a shaped spot is burned by the shaped ion beam in a sample and an image of the burned spot is acquired (e.g., by secondary emission).

At operation 1206, a shape parameter of a spot-burn profile of the spot is measured. The shape parameter may be any suitable shape parameter, including any shape parameter described herein. The shape parameter is measured by analyzing the image to identify the spot-burn profile and to identify features of the spot-burn profile, such as a midpoint of a low-angle ray portion and outermost apex points of a high-angle ray portion. The shape parameter is then measured based on the identified features of the spot-burn profile. In some examples, operation 1206 is performed by control system 300 without user input by using image recognition and image processing techniques. In other examples, operation 1206 is performed by control system 300 based on user input. For example, a user may use a pointer to indicate or select, on a graphical user interface displaying the image of the spot, the features of the spot-burn profile. Control system 300 may then measure the shape parameter based on the indicated or selected features. Alternatively, a user may measure the shape parameter using virtual measurement tools provided by the graphical user interface.

At operation 1208, it is determined, based on the measured shape parameter, whether alignment is completed. In some examples, alignment is completed when the measured shape parameter satisfies a threshold condition, as described above (e.g., when distance d1 is less than a threshold distance value, when the angle of the axis is within a threshold range, or when a ratio of d3/d2 is within a threshold range). If it is determined that alignment is completed, the shaped aperture is properly aligned and processing of method 1200 ends. If it is determined that alignment is not completed, processing continues to operation 1210.

At operation 1210, a position of the shaped aperture is adjusted based on the measured shape parameter of the spot-burn profile. The direction of the adjustment is based on the value of the measured shape parameter. In some examples, the position of the shaped aperture is adjusted one motor step of the aperture plate stage. In other examples, the magnitude of the adjustment is based on the magnitude of the measured shape parameter. For example, the magnitude of the adjustment may be proportional or otherwise correlated to the measured distance d1, the angle of the axis, or the ratio d3/d2 (or difference d3−d2). In other examples, the magnitude of the adjustment has a first size (e.g., a minimum step size) if the measured shape parameter is less than a threshold value and has a second size (e.g., a double step size) if the measured shape parameter is greater than the threshold value.

After operation 1210 is completed, processing returns to operation 1202 and method 1200 is repeated until alignment of the shaped aperture is completed.

In some examples, method 1200 is performed to align a shaped aperture in a first direction (e.g., the X direction) using a shape parameter for alignment in the first direction. After aligning the shaped aperture in the first direction, method 1200 is performed again to align the shaped aperture in a second direction (e.g., the Y direction) using a shape parameter for alignment in the second direction. Alternatively, the shaped aperture may first be aligned in the second direction and then aligned in the first direction. In yet further examples, the shaped aperture may be aligned in both the first direction and the second direction simultaneously. In these examples, multiple shape parameters are measured at operation 1206 and the aperture is adjusted in both the first direction and the second direction at operation 1210, as necessary. That is, during each iteration of method 1200, operations 1206, 1208, and 1210 are performed independently for each of the first direction and the second direction.

The alignment of the shaped aperture may be affected by other factors. The sensitivity of each alignment technique varies differently depending on the defocus value of the objective lens. There exists an optimized lens configuration for each ion beam that gives the most sensitive alignment, and this lens configuration is dependent primarily on the defocus value, which is related to the beam properties of energy, current, and accel/decel lensing.

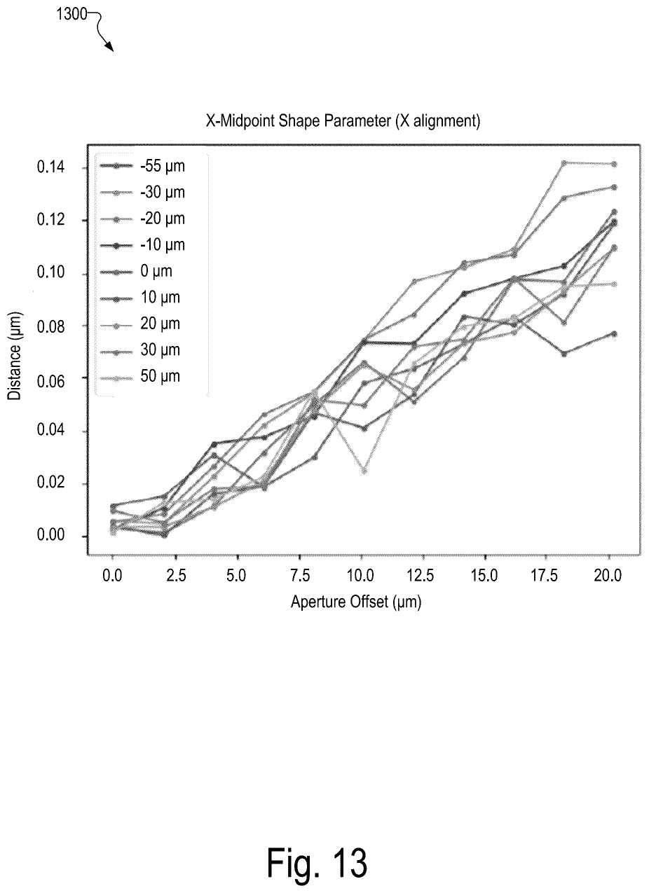

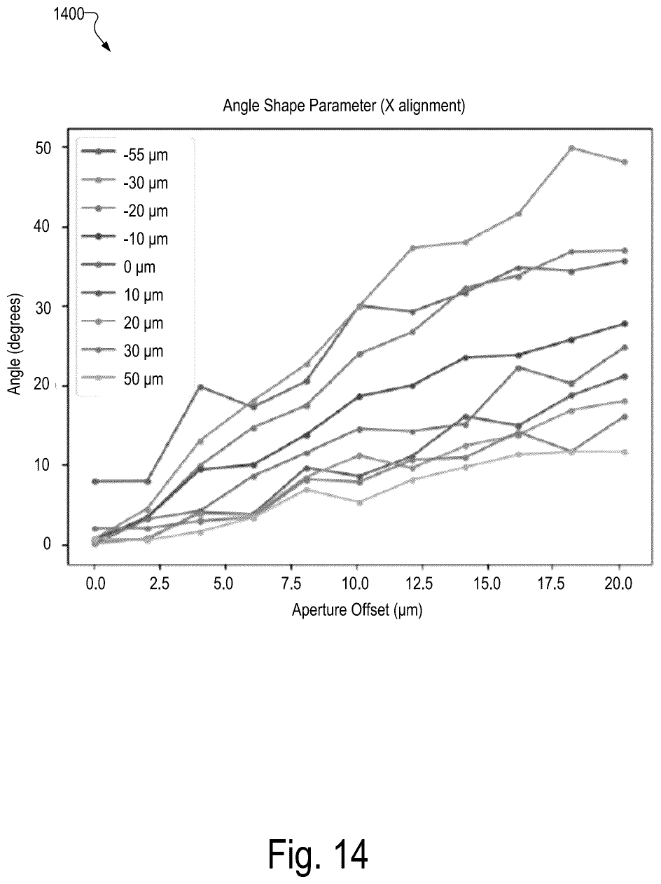

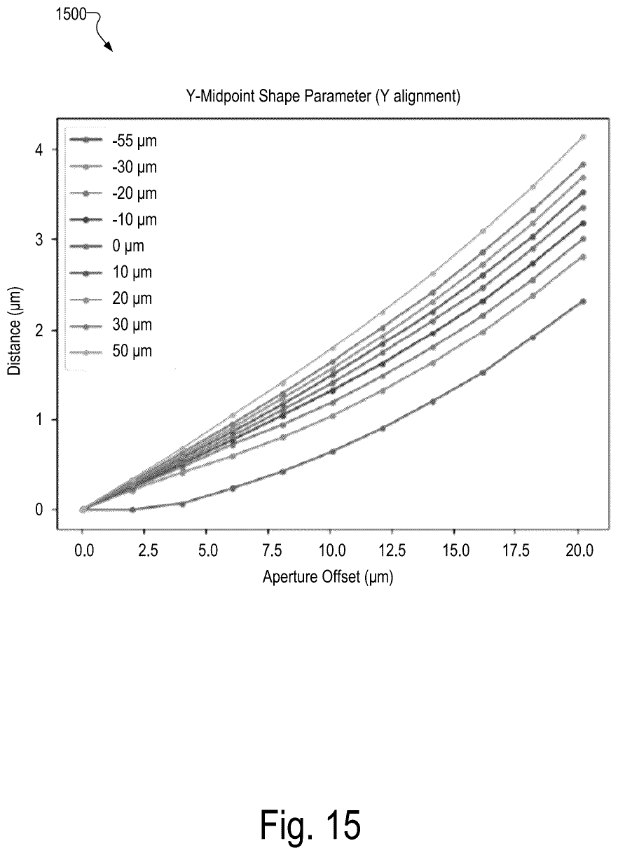

FIGS. 13-15 illustrate how the measured shape parameter as a function of aperture offset varies depending on the defocus value. FIG. 13 shows a chart 1300 that includes a set of curves that plot the measured midpoint separation in the X direction (e.g., distance d1) as a function of aperture offset, where each curve represents data acquired with a unique defocus value (e.g., defocus values of −55 μm, −30 μm, −20 μm, −10 μm, 0 μm, 10 μm, 20 μm, 30 μm, and 40 μm). FIG. 14 shows a chart 1400 that includes a set of curves that plot the measured angle of the axis as a function of aperture offset, where each curve represents data acquired with one of the unique defocus values of FIG. 13. FIG. 15 shows a chart 1500 that includes a set of curves that plot the measured midpoint separation in the Y direction as a function of aperture offset, where each curve represents data acquired with one of the unique defocus values of FIG. 13. The steeper the slope of the curves in charts 1300, 1400, and 1500, the more sensitive is the alignment. Thus, a particular defocus value will result in the most sensitive alignment of the shaped aperture. This information can be used to select the most sensitive parameters for alignment of a shaped aperture.

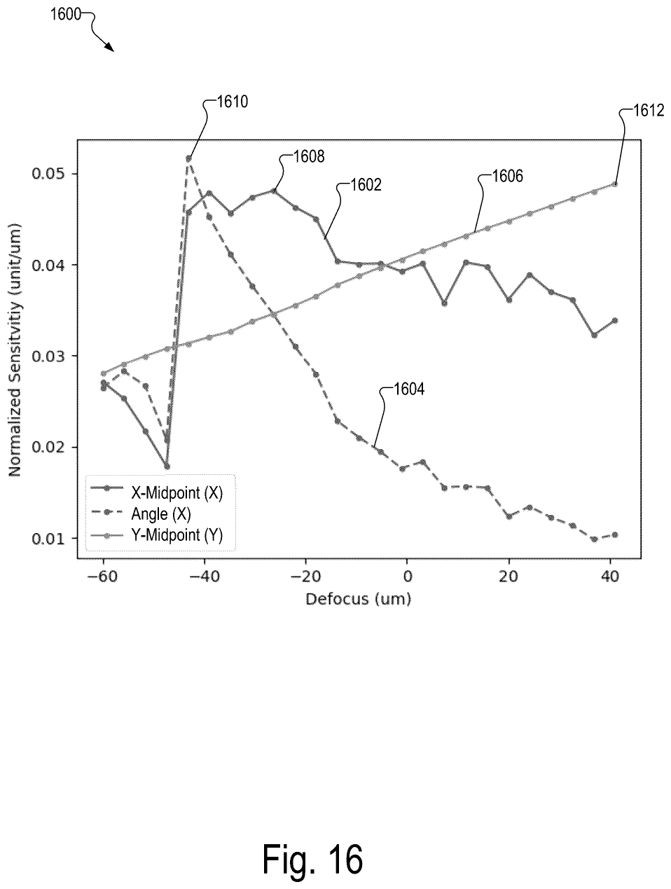

For example, FIG. 16 shows an illustrative sensitivity plot 1600 that includes a set of curves that plot normalized sensitivity as a function of defocus value (μm) for each shape parameter alignment method. Normalized sensitivity is measured as the angle of the axis normalized relative to the maximum angle of the axis, or is measured as the X-midpoint or Y-midpoint distance normalized relative to the maximum X-midpoint or Y-midpoint distance, respectively. A curve 1602 represents data acquired using the X-midpoint shape parameter. A curve 1604 represents data acquired using the angle shape parameter. A curve 1606 represents data acquired using the Y-midpoint shape parameter. An apex 1608 of curve 1602 indicates that alignment using the X-midpoint shape parameter is most sensitive at a defocus value of about −25 μm (or −40 μm). An apex 1610 of curve 1604 indicates that alignment using the angle shape parameter is most sensitive at a defocus value of about −45 μm and is more sensitive than the X-midpoint shape parameter. An apex 1612 of curve 1606 indicates that alignment using the Y-midpoint shape parameter is most sensitive at a defocus value of about +40 μm.

Using this information, the defocus value and shape parameter can be selected to achieve the most sensitive alignment of a shaped aperture. For example, method 1200 may be performed to align the shaped aperture in the X direction using the angle shape parameter with a defocus value of about −45 μm, which gives the most sensitive alignment in the X direction. Method 1200 may then be performed to align the shaped aperture in the Y direction using the Y-midpoint shape parameter with a defocus value of about +40 μm, which gives the most sensitive alignment in the Y direction.

The information represented in sensitivity plot 1600 also allows the defocus value and shape parameter to be selected to achieve the most sensitive alignment using a single burn spot. In these examples, the shaped aperture is to be aligned in both the X direction and Y direction using the same burn spot (e.g., where method 1200 is performed simultaneously for the X and Y direction alignment). The intersection of curve 1602 (X-midpoint shape parameter for alignment in X) and curve 1606 (Y-midpoint shape parameter for alignment in Y) at a defocus value of about −5 μm provides the most sensitive alignment of the aperture.

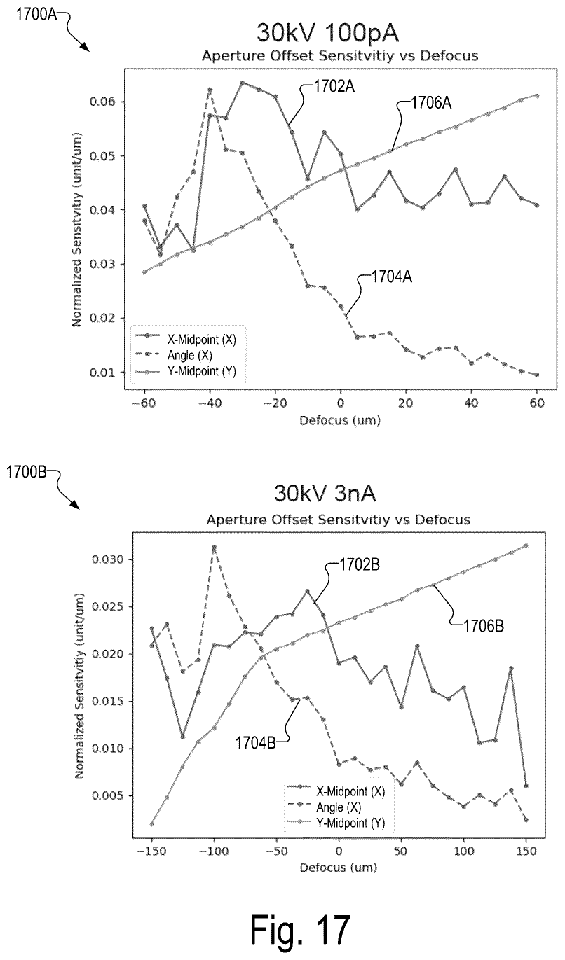

As mentioned, other parameters of the ion beam may also affect sensitivity, such as beam energy, current, and accel/decel lensing. FIG. 17 shows two different sensitivity plots 1700A and 1700B each representative of different beam conditions. Sensitivity plot 1700A represents data acquired with an ion beam having an energy of 30 kilovolts (kV) and a current of 100 picoamps (pA). Sensitivity plot 1700B represents data acquired with an ion beam having an energy of 30 kV and a current of 3 nanoamps (nA). Curves 1702A and 1702B represent data acquired using the X-midpoint shape parameter. Curves 1704A and 1704B represent data acquired using the angle shape parameter. Curves 1706A and 1706B represent data acquired using the Y-midpoint shape parameter. As can be seen in FIG. 17, spot-burn profiles produced by lower current shaped ion beams (as in the example of sensitivity plot 1700A) are slightly more sensitive to the X-midpoint shape parameter than the angle shape parameter, while spot-burn profiles produced by higher current shaped ion beams (as in the example of sensitivity plot 1700B) are more sensitive to the angle shape parameter than to the X-midpoint shape parameter.

In the case of a 100 pA beam (sensitivity plot 1700A), the X-midpoint shape parameter and a defocus value of about −30 μm give the most sensitive alignment in the X direction while the alignment in the Y direction is most sensitive with a high underfocus (e.g., about +60 μm). In the case of the 3 nA beam (sensitivity plot 1700B), the angle shape parameter and a defocus value of about −100 μm give the most sensitive alignment in the X direction while the alignment in the Y direction is most sensitive with a high underfocus (e.g., about +150 μm). Conversely, if only one spot is desired to analyze both X and Y, the X-midpoint distance shape parameter and a defocus value of about 0 μm give the most sensitive alignment for the 100 pA beam and the X-midpoint distance shape parameter and a defocus value of about −15 μm give the most sensitive alignment for the 3 nA beam. While FIG. 17 shows sensitivity plots for different beam currents, any suitable combination of beam conditions may be represented by a distinct set of sensitivity data.

In some examples, the shape parameter and defocus value that are used for alignment of a shaped aperture are selected based one or more conditions of the ion beam, such as the beam energy, current, and/or accel/decel lensing. For example, a set of sensitivity plots may include a distinct sensitivity plot for each distinct combination of beam conditions (e.g., energy, current, and/or accel/decel lensing). The set of sensitivity plots may be generated empirically in advance of an alignment of the shaped aperture. The set of sensitivity plots may be stored locally with control system 300 or may be stored and accessed remotely. An appropriate sensitivity plot may be selected based on the current beam characteristics. It will be recognized that a sensitivity plot is not necessary, as the appropriate shape parameter can be selected based on a set of sensitivity data without generating a graphical sensitivity plot.

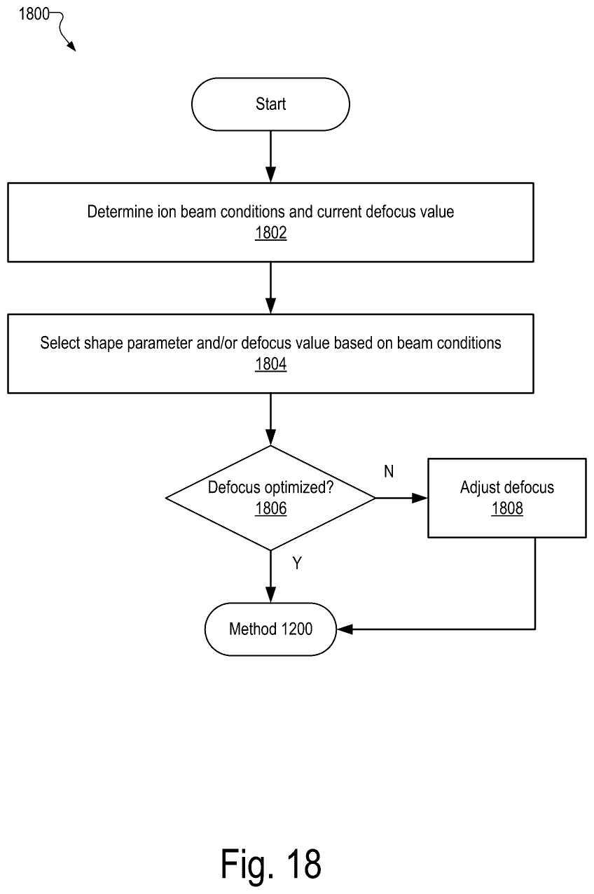

FIG. 18 shows an illustrative method 1800 of aligning a shaped aperture with an ion source based on conditions of the ion beam. While FIG. 18 shows illustrative operations according to one embodiment, other embodiments may omit, add to, reorder, and/or modify any of the operations shown in FIG. 18. Any one or more of the operations of method 500 may be performed by control system 300.

At operation 1802, ion beam conditions are determined. The ion beam conditions that may be determined include, without limitation, beam energy, beam current, magnification, and/or a defocus value (e.g., a voltage applied to the objective lens). The beam conditions may be determined in any suitable way, such as based on current FIB system settings.

At operation 1804, a shape parameter and/or a defocus value are selected based on the beam conditions determined at operation 1802. For example, a set of sensitivity data that best matches or approximates the identified beam conditions may be selected (e.g., from local storage or from a remote computing system) from a plurality of distinct sets of sensitivity data, where each distinct set of sensitivity data corresponds to a distinct set of beam conditions. Sensitivity data represents normalized sensitivity as a function of defocus value for each different alignment method (e.g., for each shape parameter). In some examples, the set of sensitivity data is selected so that the distinct set of beam conditions of the selected set of sensitivity data is the same as or similar to (e.g., within a threshold amount, such as within 3%, 5%, 10%, etc.) the beam conditions identified at operation 1802.

A shape parameter and/or a defocus value are selected based on the selected set of sensitivity data. For example, as explained above with reference to sensitivity plots 1600, 1700A, and 1700B, the shape parameter and defocus value that gives the most sensitive alignment in X may be selected and the defocus value that gives the most sensitive alignment in Y may be selected. In further examples, the shape parameter for alignment in X may be pre-set and only the defocus value that gives the most sensitive alignment in Y is selected. In yet further examples, the shape parameter and defocus value that gives the most sensitive alignment in both X and Y using a single burn spot is selected.

At operation 1806, it is determined whether the current defocus value (e.g., the voltage applied to the object lens), as determined at operation 1802, matches the defocus value selected at operation 1804. If the current defocus value matches the selected defocus value, then method 1200 is performed to align the aperture using the selected shape parameter and/or the selected defocus value. If the current defocus value identified at operation 1802 does not match the selected defocus value, then method 1800 proceeds to operation 1808.

At operation 1808, the current defocus value (e.g., the voltage applied to the objective lens) is adjusted to match the selected defocus value. Method 1200 is then performed to align the aperture using the selected shape parameter and/or the selected defocus value. In examples where the defocus value is different for the X and Y alignments, method 1200 is performed separately for each alignment using the respective defocus value selected at operation 1804.

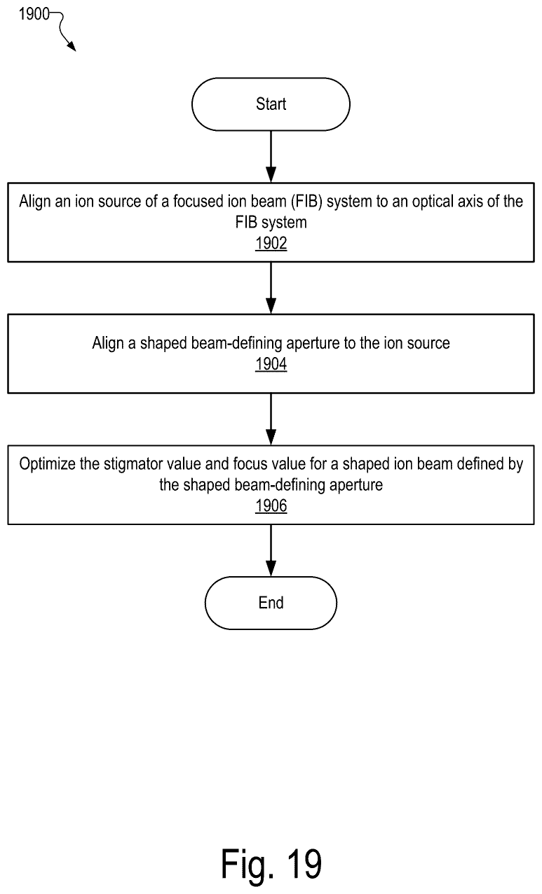

The shaped aperture alignment process described above can be combined with optimization of the stigmator voltage and defocus value in a single process. FIG. 19 shows an illustrative method 1900 of aligning a shaped aperture and optimizing the shaped beam. While FIG. 19 shows illustrative operations according to one embodiment, other embodiments may omit, add to, reorder, and/or modify any of the operations shown in FIG. 19.

At operation 1902, an ion source of an FIB system is aligned to an optical axis of the FIB system. Operation 1902 may be performed in any suitable way known to those of skill in the art.

At operation 1904, a shaped aperture is aligned to the ion source. Operation 1904 may be performed in any suitable way, including any way described herein, such as by method 1200.

At operation 1906, the stigmator voltage and focus value for a shaped ion beam defined by the shaped aperture are optimized. The stigmator voltage and focus value may be optimized in any suitable way, including any way described herein, such as by method 500.

In method 500, optimization of the stigmator voltage includes directing an ion beam through a reference (e.g., round) aperture before directing the ion beam through the shaped aperture. Accordingly, in some examples operation 1904 includes storing the determined alignment position of the shaped aperture in a memory for later access and positioning of the shaped aperture. For example a motor position of the aperture plate stage for the alignment position determined at operation 1904 may be stored in a local or remote memory. The stored alignment position may then be accessed after operation 1906 and used to position the shaped aperture prior to processing sample.

In a variation of method 1900, operation 1906 is performed before operation 1904 so that the stigmator voltage and focus value are determined for the shaped aperture, after which the shaped aperture is aligned. In another variation of method 1900, operation 1906 is split so that optimization of the reference stigmator voltage using a reference beam is performed before operation 1904 and optimization of the focus value using the shaped beam is performed after operation 1904.

In certain embodiments, one or more of the systems, components, and/or processes described herein may be implemented and/or performed by one or more appropriately configured computing devices. To this end, one or more of the systems and/or components described above may include or be implemented by any computer hardware and/or computer-implemented instructions (e.g., software) embodied on at least one non-transitory computer-readable medium configured to perform one or more of the processes described herein. In particular, system components may be implemented on one physical computing device or may be implemented on more than one physical computing device. Accordingly, system components may include any number of computing devices, and may employ any of a number of computer operating systems.

In certain embodiments, one or more of the processes described herein may be implemented at least in part as instructions embodied in a non-transitory computer-readable medium and executable by one or more computing devices. In general, a processor (e.g., a microprocessor) receives instructions, from a non-transitory computer-readable medium, (e.g., a memory, etc.), and executes those instructions, thereby performing one or more processes, including one or more of the processes described herein. Such instructions may be stored and/or transmitted using any of a variety of known computer-readable media.

A computer-readable medium (also referred to as a processor-readable medium) includes any non-transitory medium that participates in providing data (e.g., instructions) that may be read by a computer (e.g., by a processor of a computer). Such a medium may take many forms, including, but not limited to, non-volatile media, and/or volatile media. Non-volatile media may include, for example, optical or magnetic disks and other persistent memory. Volatile media may include, for example, dynamic random access memory (“DRAM”), which typically constitutes a main memory. Common forms of computer-readable media include, for example, a disk, hard disk, magnetic tape, any other magnetic medium, a compact disc read-only memory (“CD-ROM”), a digital video disc (“DVD”), any other optical medium, random access memory (“RAM”), programmable read-only memory (“PROM”), electrically erasable programmable read-only memory (“EPROM”), FLASH-EEPROM, any other memory chip or cartridge, or any other tangible medium from which a computer can read.

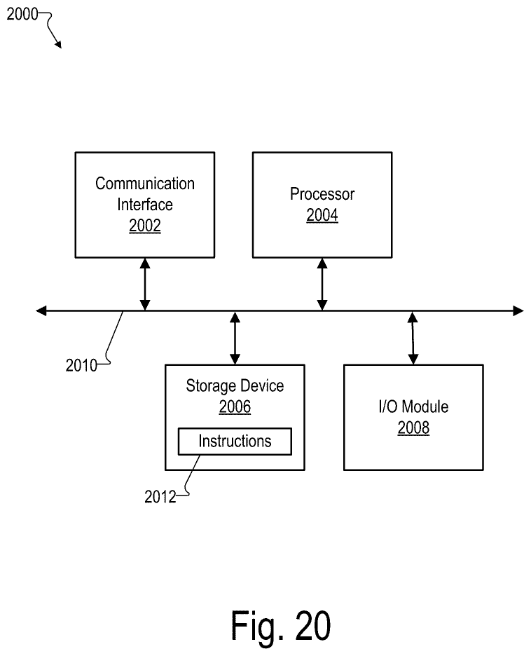

FIG. 20 shows an illustrative computing device 2000 that may be specifically configured to perform one or more of the processes described herein. As shown in FIG. 20, computing device 2000 may include a communication interface 2002, a processor 2004, a storage device 2006, and an input/output (“I/O”) module 2008 communicatively connected one to another via a communication infrastructure 2010. While an illustrative computing device 2000 is shown in FIG. 20, the components illustrated in FIG. 20 are not intended to be limiting. Additional or alternative components may be used in other embodiments. Components of computing device 2000 shown in FIG. 20 will now be described in additional detail.

Communication interface 2002 may be configured to communicate with one or more computing devices. Examples of communication interface 2002 include, without limitation, a wired network interface (such as a network interface card), a wireless network interface (such as a wireless network interface card), a modem, an audio/video connection, and any other suitable interface.

Processor 2004 generally represents any type or form of processing unit capable of processing data and/or interpreting, executing, and/or directing execution of one or more of the instructions, processes, and/or operations described herein. Processor 2004 may perform operations by executing computer-executable instructions 2012 (e.g., an application, software, code, and/or other executable data instance) stored in storage device 2006.

Storage device 2006 may include one or more data storage media, devices, or configurations and may employ any type, form, and combination of data storage media and/or device. For example, storage device 2006 may include, but is not limited to, any combination of the non-volatile media and/or volatile media described herein. Electronic data, including data described herein, may be temporarily and/or permanently stored in storage device 2006. For example, data representative of computer-executable instructions 2012 configured to direct processor 2004 to perform any of the operations described herein may be stored within storage device 2006. In some examples, data may be arranged in one or more databases residing within storage device 2006.

I/O module 2008 may include one or more I/O modules configured to receive user input and provide user output. One or more I/O modules may be used to receive input for a single virtual experience. I/O module 2008 may include any hardware, firmware, software, or combination thereof supportive of input and output capabilities. For example, I/O module 2008 may include hardware and/or software for capturing user input, including, but not limited to, a keyboard or keypad, a touchscreen component (e.g., touchscreen display), a receiver (e.g., an RF or infrared receiver), motion sensors, and/or one or more input buttons.

I/O module 2008 may include one or more devices for presenting output to a user, including, but not limited to, a graphics engine, a display (e.g., a display screen), one or more output drivers (e.g., display drivers), one or more audio speakers, and one or more audio drivers. In certain embodiments, I/O module 2008 is configured to provide graphical data to a display for presentation to a user. The graphical data may be representative of one or more graphical user interfaces and/or any other graphical content as may serve a particular implementation.

In some examples, any of the systems, computing devices, and/or other components described herein may be implemented by computing device 2000. For example, memory 302 may be implemented by storage device 2006, and processor 304 may be implemented by processor 2004.

It will be recognized by those of ordinary skill in the art that while, in the preceding description, various illustrative embodiments have been described with reference to the accompanying drawings. It will, however, be evident that various modifications and changes may be made thereto, and additional embodiments may be implemented, without departing from the scope of the invention as set forth in the claims that follow. For example, certain features of one embodiment described herein may be combined with or substituted for features of another embodiment described herein. The description and drawings are accordingly to be regarded in an illustrative rather than a restrictive sense.

Advantages and features of the present disclosure can be further described by the following examples:

Example 1. A focused ion beam system comprising: an ion source; an aperture plate comprising a reference beam-defining aperture and a shaped beam-defining aperture; a stigmator; an objective lens for focusing the ion beam on a target plane; and a controller configured to: direct the ion source to emit ions to form an ion beam; determine, while the ion beam passes through the reference beam-defining aperture to form a reference beam, a reference stigmator voltage for operating the stigmator to minimize a dimension of the reference beam; and determine, after determining the reference stigmator voltage and while the ion beam passes through the shaped beam-defining aperture to form a shaped working beam and while operating the stigmator using the reference stigmator voltage, a focus value of the objective lens to optimize a size of the shaped working beam; wherein a shape of the shaped working beam is different from a shape of the reference beam and has a first dimension corresponding to the dimension of the reference beam and a second dimension larger than the first dimension.

Example 2. The focused ion beam system of example 1, wherein determining the focus value of the objective lens comprises minimizing the first dimension or the second dimension of the shaped working beam.

Example 3. The focused ion beam system of example 1, wherein determining the focus value of the objective lens comprises: measuring the first dimension or the second dimension of the shaped working beam for each of a plurality of focus values; and selecting, as the focus value of the objective lens, the focus value of the plurality of focus values corresponding to a minimum value of the first dimension or the second dimension.

Example 4. The focused ion beam system of any of the preceding examples, wherein determining the reference stigmator voltage comprises: measuring the dimension of the reference beam for each of a plurality of stigmator voltages; and selecting, as the reference stigmator voltage, a stigmator voltage corresponding to a minimum value of the dimension of the reference beam.

Example 5. The focused ion beam system of any of the preceding examples, wherein the shape of the reference beam is round.

Example 6. The focused ion beam system of any of the preceding examples, wherein the shape of the working beam is elliptical.

Example 7. The focused ion beam system of any of the preceding examples, wherein an aspect ratio of the second dimension to the first dimension is 2:1 or greater.

Example 8. The focused ion beam system of any of the preceding examples, wherein an aspect ratio of the second dimension to the first dimension is 3:1 or greater.

Example 9. A non-transitory computer-readable medium storing instructions that, when executed, direct at least one processor of a computing device for a focused ion beam system to: direct an ion source to emit ions to form an ion beam extending through an optical column comprising a stigmator and an objective lens for focusing the ion beam on a target plane; determine, while the ion beam passes through a reference beam-defining aperture to form a reference beam, a reference stigmator voltage for operating the stigmator to minimize a dimension of the reference beam; and determine, after determining the reference stigmator voltage and while the ion beam passes through a shaped beam-defining aperture to form a shaped working beam and while operating the stigmator using the reference stigmator voltage, a focus value of the objective lens to optimize a size of the shaped working beam; wherein a shape of the shaped working beam is different from a shape of the reference beam and has a first dimension corresponding to the dimension of the reference beam and a second dimension larger than the first dimension.

Example 10. The computer-readable medium of example 9, wherein determining the focus value of the objective lens comprises minimizing the first dimension or the second dimension of the shaped working beam.

Example 11. The computer-readable medium of example 9, wherein determining the focus value of the objective lens comprises: measuring the first dimension or the second dimension of the shaped working beam for each of a plurality of focus values; and selecting, as the focus value of the objective lens, the focus value of the plurality of focus values corresponding to a minimum value of the first dimension or the second dimension.

Example 12. The computer-readable medium of any of examples 9-11, wherein determining the reference stigmator voltage comprises: measuring the dimension of the reference beam for each of a plurality of stigmator voltages; and selecting, as the reference stigmator voltage, a stigmator voltage corresponding to a minimum value of the dimension of the reference beam.

Example 13. The computer-readable medium of any of examples 9-12, wherein the shape of the reference beam is round.

Example 14. The computer-readable medium of any of examples 9-13, wherein the shape of the working beam is elliptical.

Example 15. The computer-readable medium of any of examples 9-14, further comprising: aligning the shaped beam-defining aperture to the ion source based on a spot-burn profile of the shaped working beam.

Example 16. The computer-readable medium of example 15, wherein alignment of the shaped beam-defining aperture in a first direction corresponding to the first dimension is based on a distance, along the first direction, between a midpoint of a low-angle ray portion of the spot-burn profile and an axis connecting outermost apex points of a high-angle ray portion of the spot-burn profile.

Example 17. The computer-readable medium of example 15, wherein alignment of the shaped beam-defining aperture in a first direction corresponding to the first dimension is based on an angle formed by an axis connecting outermost apex points of a high-angle ray portion of the spot-burn profile through a midpoint of a low-angle ray portion of the spot-burn profile.

Example 18. The computer-readable medium of any of examples 15-17, wherein alignment of the shaped beam-defining aperture in a second direction corresponding to the second dimension is based on a distance, along the second direction, between a midpoint of a low-angle ray portion of the spot-burn profile and one or both outermost apex points of a high-angle ray portion of the spot-burn profile.

Example 19. The computer-readable medium of example 15, wherein the aligning the shaped beam-defining aperture to the ion source comprises: determining beam conditions of the ion beam; selecting, based on the beam conditions of the ion beam, a shape parameter and a focus value for the objective lens; setting the focus value of the objective lens based on the selected focus value; and measuring the shape parameter in the spot-burn profile of the shaped working beam.

Example 20. The computer-readable medium of example 19, wherein the beam conditions include at least one of beam current or beam energy.

Example 21. A system comprising: one or more processors; and memory storing executable instructions that, when executed by the one or more processors, cause a computing device to: direct an ion source to emit ions to form an ion beam extending through an optical column comprising a stigmator and an objective lens for focusing the ion beam on a target plane; determine, while the ion beam passes through a reference beam-defining aperture to form a reference beam, a reference stigmator voltage for operating the stigmator to minimize a dimension of the reference beam; and determine, after determining the reference stigmator voltage and while the ion beam passes through a shaped beam-defining aperture to form a shaped working beam and while operating the stigmator using the reference stigmator voltage, a focus value of the objective lens to optimize a size of the shaped working beam; wherein a shape of the shaped working beam is different from a shape of the reference beam and has a first dimension corresponding to the dimension of the reference beam and a second dimension larger than the first dimension.

Example 22. The system of example 21, wherein determining the focus value of the objective lens comprises minimizing the first dimension or the second dimension of the shaped working beam.

Example 23. The system of example 21, wherein determining the focus value of the objective lens comprises: measuring the first dimension or the second dimension of the shaped working beam for each of a plurality of focus values; and selecting, as the focus value of the objective lens, the focus value of the plurality of focus values corresponding to a minimum value of the first dimension or the second dimension.

Example 24. The system of any of examples 21-23, wherein determining the reference stigmator voltage comprises: measuring the dimension of the reference beam for each of a plurality of stigmator voltages; and selecting, as the reference stigmator voltage, a stigmator voltage corresponding to a minimum value of the dimension of the reference beam.

Example 25. The system of any of examples 21-24, wherein the shape of the reference beam is round.

Example 26. The system of any of examples 21-25, wherein the shape of the working beam is elliptical.

Example 27. A method of optimizing a shaped working beam, comprising: directing an ion source to emit ions to form an ion beam extending through an optical column comprising a stigmator and an objective lens for focusing the ion beam on a target plane; directing the ion beam through a reference beam-defining aperture to form a reference beam; determining a reference stigmator voltage for operating the stigmator to minimize a dimension of the reference beam; directing, after the determining the reference stigmator voltage, the ion beam through a shaped beam-defining aperture to form the shaped working beam, wherein a shape of the shaped working beam is different from a shape of the reference beam and has a first dimension corresponding to the dimension of the reference beam and a second dimension larger than the first dimension; and determining, while operating the stigmator using the reference stigmator voltage, a focus value of the objective lens to optimize a size of the shaped working beam.

Example 28. The method of example 27, wherein the determining the focus value of the objective lens comprises minimizing the first dimension or the second dimension of the shaped working beam.

Example 29. The method of example 27, wherein the determining the focus value of the objective lens comprises: measuring the first dimension or the second dimension of the shaped working beam for each of a plurality of focus values; and selecting, as the focus value of the objective lens, the focus value of the plurality of focus values corresponding to a minimum value of the first dimension or the second dimension.

Example 30. The method of any of examples 27-29, wherein the determining the reference stigmator voltage comprises: measuring the dimension of the reference beam for each of a plurality of stigmator voltages; and selecting, as the reference stigmator voltage, a stigmator voltage corresponding to a minimum value of the dimension of the reference beam.

Example 31. The method of any of examples 27-30, wherein the shape of the reference beam is round.

Example 32. The method of any of examples 27-31, wherein the shape of the working beam is elliptical.

Example 33. The method of any of examples 27-32, further comprising: aligning the shaped beam-defining aperture to the ion source based on a spot-burn profile of the shaped working beam.

Example 34. The method of example 33, wherein alignment of the shaped beam-defining aperture in a first direction corresponding to the first dimension is based on a distance, along the first direction, between a midpoint of a low-angle ray portion of the spot-burn profile and an axis connecting outermost apex points of a high-angle ray portion of the spot-burn profile.

Example 35. The method of example 33, wherein alignment of the shaped beam-defining aperture in a first direction corresponding to the first dimension is based on an angle formed by an axis connecting outermost apex points of a high-angle ray portion of the spot-burn profile through a midpoint of a low-angle ray portion of the spot-burn profile.

Example 36. The method of any of examples 33-35, wherein alignment of the shaped beam-defining aperture in a second direction corresponding to the second dimension is based on a distance, along the second direction, between a midpoint of a low-angle ray portion of the spot-burn profile and one or both outermost apex points of a high-angle ray portion of the spot-burn profile.

Example 37. The method of example 33, wherein the aligning the shaped beam-defining aperture to the ion source comprises: determining beam conditions of the ion beam; selecting, based on the beam conditions of the ion beam, a shape parameter and a focus value for the objective lens; setting the focus value of the objective lens based on the selected focus value; and measuring the shape parameter in the spot-burn profile of the shaped working beam.

Example 38. The method of example 37, wherein the beam conditions include at least one of beam current or beam energy.

What is claimed is:

1. A focused ion beam system comprising:
an ion source;
an aperture plate comprising a reference beam-defining aperture and a shaped beam-defining aperture;
a stigmator;
an objective lens for focusing an ion beam on a target plane; and
a controller configured to:
direct the ion source to emit ions to form the ion beam;
determine, while the ion beam passes through the reference beam-defining aperture to form a reference beam, a reference stigmator voltage for operating the stigmator to minimize a dimension of the reference beam; and
determine, after determining the reference stigmator voltage and while the ion beam passes through the shaped beam-defining aperture to form a shaped working beam and while operating the stigmator using the reference stigmator voltage, a focus value of the objective lens to optimize a size of the shaped working beam;
wherein a shape of the shaped working beam is different from a shape of the reference beam and has a first dimension corresponding to the dimension of the reference beam and a second dimension larger than the first dimension.

2. The focused ion beam system of claim 1, wherein determining the focus value of the objective lens comprises minimizing the first dimension or the second dimension of the shaped working beam.

3. The focused ion beam system of claim 1, wherein determining the focus value of the objective lens comprises:
measuring the first dimension or the second dimension of the shaped working beam for each of a plurality of focus values; and
selecting, as the focus value of the objective lens, the focus value of the plurality of focus values corresponding to a minimum value of the first dimension or the second dimension.

4. The focused ion beam system of claim 1, wherein determining the reference stigmator voltage comprises:
measuring the dimension of the reference beam for each of a plurality of stigmator voltages; and
selecting, as the reference stigmator voltage, a stigmator voltage corresponding to a minimum value of the dimension of the reference beam.

5. The focused ion beam system of claim 1, wherein the shape of the reference beam is round.

6. The focused ion beam system of claim 1, wherein the shape of the working beam is elliptical.

7. The focused ion beam system of claim 1, wherein an aspect ratio of the second dimension to the first dimension is 2:1 or greater.

8. The focused ion beam system of claim 1, wherein an aspect ratio of the second dimension to the first dimension is 3:1 or greater.

9. A non-transitory computer-readable medium storing instructions that, when executed, direct at least one processor of a computing device for a focused ion beam system to:
direct an ion source to emit ions to form an ion beam extending through an optical column comprising a stigmator and an objective lens for focusing the ion beam on a target plane;
determine, while the ion beam passes through a reference beam-defining aperture to form a reference beam, a reference stigmator voltage for operating the stigmator to minimize a dimension of the reference beam; and
determine, after determining the reference stigmator voltage and while the ion beam passes through a shaped beam-defining aperture to form a shaped working beam and while operating the stigmator using the reference stigmator voltage, a focus value of the objective lens to optimize a size of the shaped working beam;
wherein a shape of the shaped working beam is different from a shape of the reference beam and has a first dimension corresponding to the dimension of the reference beam and a second dimension larger than the first dimension.

10. The computer-readable medium of claim 9, wherein determining the focus value of the objective lens comprises minimizing the first dimension or the second dimension of the shaped working beam.

11. The computer-readable medium of claim 9, wherein determining the focus value of the objective lens comprises:
measuring the first dimension or the second dimension of the shaped working beam for each of a plurality of focus values; and
selecting, as the focus value of the objective lens, the focus value of the plurality of focus values corresponding to a minimum value of the first dimension or the second dimension.

12. The computer-readable medium of claim 9, wherein determining the reference stigmator voltage comprises:
measuring the dimension of the reference beam for each of a plurality of stigmator voltages; and
selecting, as the reference stigmator voltage, a stigmator voltage corresponding to a minimum value of the dimension of the reference beam.

13. The computer-readable medium of claim 9, wherein the shape of the reference beam is round.

14. The computer-readable medium of claim 9, wherein the shape of the working beam is elliptical.

15. The computer-readable medium of claim 9, further comprising:
aligning the shaped beam-defining aperture to the ion source based on a spot-burn profile of the shaped working beam.

16. The computer-readable medium of claim 15, wherein alignment of the shaped beam-defining aperture in a first direction corresponding to the first dimension is based on a distance, along the first direction, between a midpoint of a low-angle ray portion of the spot-burn profile and an axis connecting outermost apex points of a high-angle ray portion of the spot-burn profile.

17. The computer-readable medium of claim 15, wherein alignment of the shaped beam-defining aperture in a first direction corresponding to the first dimension is based on an angle formed by an axis connecting outermost apex points of a high-angle ray portion of the spot-burn profile through a midpoint of a low-angle ray portion of the spot-burn profile.

18. The computer-readable medium of claim 15, wherein alignment of the shaped beam-defining aperture in a second direction corresponding to the second dimension is based on a distance, along the second direction, between a midpoint of a low-angle ray portion of the spot-burn profile and one or both outermost apex points of a high-angle ray portion of the spot-burn profile.

19. The computer-readable medium of claim 15, wherein the aligning the shaped beam-defining aperture to the ion source comprises:
determining beam conditions of the ion beam;
selecting, based on the beam conditions of the ion beam, a shape parameter and a focus value for the objective lens;
setting the focus value of the objective lens based on the selected focus value; and
measuring the shape parameter in the spot-burn profile of the shaped working beam.

20. The computer-readable medium of claim 19, wherein the beam conditions include at least one of beam current or beam energy.

21. A system comprising:
one or more processors; and
memory storing executable instructions that, when executed by the one or more processors, cause a computing device to:
direct an ion source to emit ions to form an ion beam extending through an optical column comprising a stigmator and an objective lens for focusing the ion beam on a target plane;
determine, while the ion beam passes through a reference beam-defining aperture to form a reference beam, a reference stigmator voltage for operating the stigmator to minimize a dimension of the reference beam; and
determine, after determining the reference stigmator voltage and while the ion beam passes through a shaped beam-defining aperture to form a shaped working beam and while operating the stigmator using the reference stigmator voltage, a focus value of the objective lens to optimize a size of the shaped working beam;
wherein a shape of the shaped working beam is different from a shape of the reference beam and has a first dimension corresponding to the dimension of the reference beam and a second dimension larger than the first dimension.

22. The system of claim 21, wherein determining the focus value of the objective lens comprises minimizing the first dimension or the second dimension of the shaped working beam.

23. The system of claim 21, wherein determining the focus value of the objective lens comprises:
measuring the first dimension or the second dimension of the shaped working beam for each of a plurality of focus values; and
selecting, as the focus value of the objective lens, the focus value of the plurality of focus values corresponding to a minimum value of the first dimension or the second dimension.

24. The system of claim 21, wherein determining the reference stigmator voltage comprises:
measuring the dimension of the reference beam for each of a plurality of stigmator voltages; and
selecting, as the reference stigmator voltage, a stigmator voltage corresponding to a minimum value of the dimension of the reference beam.

25. The system of claim 21, wherein the shape of the reference beam is round.

26. The system of claim 21, wherein the shape of the working beam is elliptical.
